(19) United States
(12) Patent Application Publication
(10) Pub. No.: US 2026/0206339 A1
(43) Pub. Date: Jul. 16, 2026

(54) IMAGE SENSOR

(71) Applicant: Samsung Electronics Co., Ltd., Suwon-si (KR)

(72) Inventors: Yeonsoo AHN, Suwon-si (KR); Incheol CHO, Suwon-si (KR); Ho-Chul JI, Suwon-si (KR); Sung In KIM, Suwon-si (KR)

(73) Assignee: Samsung Electronics Co., Ltd., Suwon-si (KR)

(21) Appl. No.: 19/410,756

(22) Filed: Dec. 5, 2025

(30) Foreign Application Priority Data
Jan. 10, 2025 (KR) 10-2025-0004210

(51) Int. Cl. H10F 39/00; H10F 39/18

(52) U.S. Cl. CPC H10F 39/80373; H10F 39/182; H10F 39/8053; H10F 39/8063; H10F 39/807

(57) ABSTRACT

An image sensor may include a semiconductor substrate of a first conductivity type, an isolation structure in the semiconductor substrate to define pixel regions, a shallow trench isolation pattern in the semiconductor substrate to define an active portion in each of the pixel regions, a transfer gate electrode between a photoelectric conversion region and a floating diffusion region, in each of the pixel regions, and pixel transistors in the pixel regions, respectively. Each of the pixel transistors may include a pixel gate electrode on the active portion, and source/drain regions in the active portion at both sides of the pixel gate electrode. The transfer gate electrodes on the pixel regions and the pixel gate electrodes of the pixel transistors may include dopants of the first conductivity type. The source/drain regions may include dopants of a second conductivity type.

### CROSS-REFERENCE TO RELATED APPLICATIONS

This U.S. non-provisional patent application claims priority under 35 U.S.C. § 119 to Korean Patent Application No. 10-2025-0004210, filed on Jan. 10, 2025 in the Korean Intellectual Property Office, the entire contents of which are hereby incorporated by reference.

### BACKGROUND

The present disclosure relates to an image sensor, and in particular, to an image sensor with improved electrical and optical characteristics.

An image sensor is a device that converts optical signals into electrical signals. With the development of the computer and communications industries, demand may increase for high-performance image sensors in a variety of applications such as digital cameras, camcorders, personal communication systems, gaming machines, security cameras, micro-cameras for medical applications, and/or robots.

The image sensors are generally classified into charge-coupled device (CCD) and complementary metal-oxide semiconductor (CMOS) image sensors. The CMOS image sensor can be operated in a simplified manner, and since signal-processing circuits of the CMOS image sensor can be integrated on a single chip, it may be possible to reduce a size of a product therewith. In addition, since the CMOS image sensor can be operated with a relatively low power consumption, it may be more easily applied to an electronic device with a limited battery capacity. Furthermore, since the CMOS image sensor can be fabricated using the existing CMOS fabrication techniques, it may be possible to reduce a manufacturing cost thereof. In addition, owing to an increase in resolution of CMOS image sensors, the use of CMOS image sensors is rapidly increasing.

### SUMMARY

An embodiment of the inventive concept provides an image sensor with improved electrical and optical characteristics.

According to an embodiment of the inventive concept, an image sensor may include a semiconductor substrate of a first conductivity type; an isolation structure in the semiconductor substrate, the isolation structure defining pixel regions; a shallow trench isolation pattern in the semiconductor substrate, the shallow trench isolation pattern defining an active portion in each of the pixel regions; a transfer gate electrode between a photoelectric conversion region and a floating diffusion region, in each of the pixel regions; and pixel transistors in the pixel regions, respectively. Each of the pixel transistors may include a pixel gate electrode on the active portion, and source/drain regions in the active portion at both sides of the pixel gate electrode. The transfer gate electrode in each of the pixel regions may provide transfer gate electrodes on the pixel regions, respectively. The pixel gate electrode in each of the pixel transistors may provide pixel gate electrodes of the pixel transistors. The transfer gate electrodes on the pixel regions and the pixel gate electrodes of the pixel transistors may include dopants of the first conductivity type. The source/drain regions may include dopants of a second conductivity type.

According to an embodiment of the inventive concept, an image sensor may include a semiconductor substrate of a first conductivity type; an isolation structure in the semiconductor substrate, the isolation structure defining pixel regions; a shallow trench isolation pattern in the semiconductor substrate, the shallow trench isolation pattern defining an active portion in each of the pixel regions to provide active portions in the pixel regions, respectively; a photoelectric conversion region in each of the pixel regions and in the semiconductor substrate, the photoelectric conversion region comprising dopants of a second conductivity type; a floating diffusion region in each of the pixel regions and in the semiconductor substrate, the floating diffusion region being spaced apart from the photoelectric conversion region; a transfer gate electrode between the photoelectric conversion region and the floating diffusion region, in each of the pixel regions; a source follower gate electrode on a first active portion, which is one of the active portions in the pixel regions; first fin active patterns between the first active portion and the source follower gate electrode; and first source/drain regions in the first active portion at both sides of the source follower gate electrode. The transfer gate electrode and the source follower gate electrode may include the dopants of the first conductivity type.

According to an embodiment of the inventive concept, an image sensor may include a semiconductor substrate of a first conductivity type, an isolation structure in the semiconductor substrate, a plurality of transfer gate electrodes, a shallow trench isolation pattern, pixel transistors, color filters, a grid, and micro lenses on the color filters. A first surface of the semiconductor substrate may be opposite a second surface of the semiconductor substrate. The isolation structure may define a first pixel region, a second pixel region, a third pixel region, and a fourth pixel region in the semiconductor substrate. The first pixel region, the second pixel region, the third pixel region, and the fourth pixel region each may include: a first photoelectric conversion region, a second photoelectric conversion region, a third photoelectric conversion region, and a fourth photoelectric conversion region; and a first floating diffusion region, a second floating diffusion region, a third floating diffusion region, and a fourth floating diffusion region in the first pixel region, the second pixel region, the third pixel region, and the fourth pixel region, respectively, and spaced apart from the first photoelectric conversion region, the second photoelectric conversion region, the third photoelectric conversion region, and the fourth photoelectric conversion region. The plurality of transfer gate electrodes each may have a bottom surface at a level between the first surface of the semiconductor substrate and the second surface of the semiconductor substrate. The plurality of transfer gate electrodes may include a first transfer gate electrode between the first photoelectric conversion region and the first floating diffusion region, a second transfer gate electrode between the second photoelectric conversion region and the second floating diffusion region, a third transfer gate electrode between the third photoelectric conversion region and the third floating diffusion region, and a fourth transfer gate electrode between the fourth photoelectric conversion region and the fourth floating diffusion region. The shallow trench isolation pattern may be adjacent to the first surface of the semiconductor substrate. The shallow trench isolation pattern may define an active portion in each of the first pixel region, the second pixel region, the third pixel region, and the fourth pixel region to provide active portions, respectively, in the first pixel region, the second pixel region, the third pixel region, and the fourth pixel region. The pixel transistors may be on the active portions, respectively, in the first pixel region, the second pixel region, the third pixel region, and the fourth pixel region. The color filters may be on the second surface of the semiconductor substrate, and the color filters respectively may correspond to the first pixel region, the second pixel region, the third pixel region, and the fourth pixel region. The grid may be between the color filters and the grid may overlap the isolation structure. Each of the pixel transistors may include fin active patterns, a pixel gate electrode crossing the fin active patterns, and source/drain regions in the active portion at both sides of the pixel gate electrode. In each of the pixel transistors, the fin active patterns may protrude from the active portion in each of the first pixel region, the second pixel region, the third pixel region, and the fourth pixel region. The pixel gate electrode in each of the pixel transistors may provide pixel gate electrodes of the pixel transistors. The pixel gate electrodes of the pixel transistors, the first transfer gate electrode, the second transfer gate electrode, the third transfer gate electrode, and the fourth transfer gate electrode may comprise dopants of the first conductivity type. The source/drain regions of the pixel transistors may comprise dopants of a second conductivity type.

### BRIEF DESCRIPTION OF THE DRAWINGS

FIG. 1A is a circuit diagram illustrating a unit pixel of a pixel array according to an embodiment of the inventive concept.

FIG. 1B is a circuit diagram illustrating a unit pixel of a pixel array according to an embodiment of the inventive concept.

FIG. 2 is a plan view illustrating a unit pixel of an image sensor according to an embodiment of the inventive concept.

FIG. 3A is a sectional view, which is taken along lines A-A′ and D-D′ of FIG. 2 to illustrate an image sensor according to an embodiment of the inventive concept.

FIG. 3B is a sectional view, which is taken along lines B-B′ and E-E′ of FIG. 2 to illustrate an image sensor according to an embodiment of the inventive concept.

FIG. 3C is a sectional view, which is taken along a line C-C′ of FIG. 2 to illustrate an image sensor according to an embodiment of the inventive concept.

FIGS. 4 and 5 are sectional views, which are taken along the lines A-A′, B-B′, and C-C′ of FIG. 2 to illustrate an image sensor according to an embodiment of the inventive concept.

FIG. 6 is a plan view illustrating a unit pixel of an image sensor according to an embodiment of the inventive concept.

FIG. 7 is a sectional view, which is taken along lines A-A′, B-B′, and C-C′ of FIG. 6 to illustrate an image sensor according to an embodiment of the inventive concept.

FIG. 8 is a plan view illustrating a unit pixel of an image sensor according to an embodiment of the inventive concept.

FIG. 9 is a sectional view, which is taken along lines A-A′, B-B′, and C-C′ of FIG. 8 to illustrate an image sensor according to an embodiment of the inventive concept.

FIG. 10 is a plan view illustrating a unit pixel of an image sensor according to an embodiment of the inventive concept.

FIG. 11 is a sectional view, which is taken along lines A-A′, B-B′, and C-C′ of FIG. 10 to illustrate an image sensor according to an embodiment of the inventive concept.

FIG. 12 is a plan view illustrating a unit pixel of an image sensor according to an embodiment of the inventive concept.

FIG. 13 is a sectional view, which is taken along lines A-A′, B-B′, and C-C′ of FIG. 12 to illustrate an image sensor according to an embodiment of the inventive concept.

FIGS. 14 and 15 are plan views illustrating a unit pixel of an image sensor according to an embodiment of the inventive concept.

FIG. 16 is a sectional view, which is taken along lines F-F′ of FIGS. 14 and 15 to illustrate an image sensor according to an embodiment of the inventive concept.

FIG. 17 is a plan view illustrating an image sensor according to an embodiment of the inventive concept.

FIG. 18 is a plan view schematically illustrating an image sensor according to an embodiment of the inventive concept.

FIGS. 19 and 20 are sectional views, which are taken along a line I-I′ of FIG. 18 to illustrate an image sensor according to an embodiment of the inventive concept.

### DETAILED DESCRIPTION

Example embodiments of the inventive concepts will now be described more fully with reference to the accompanying drawings, in which example embodiments are shown.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

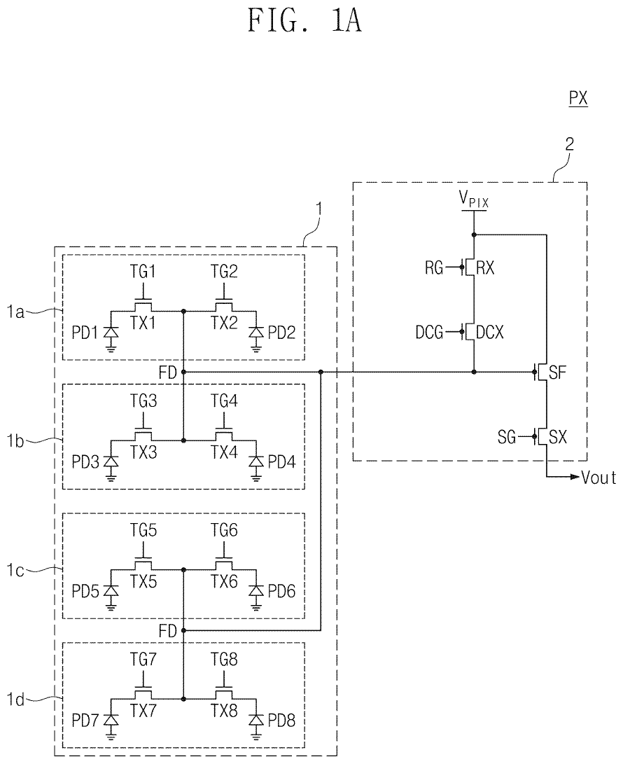

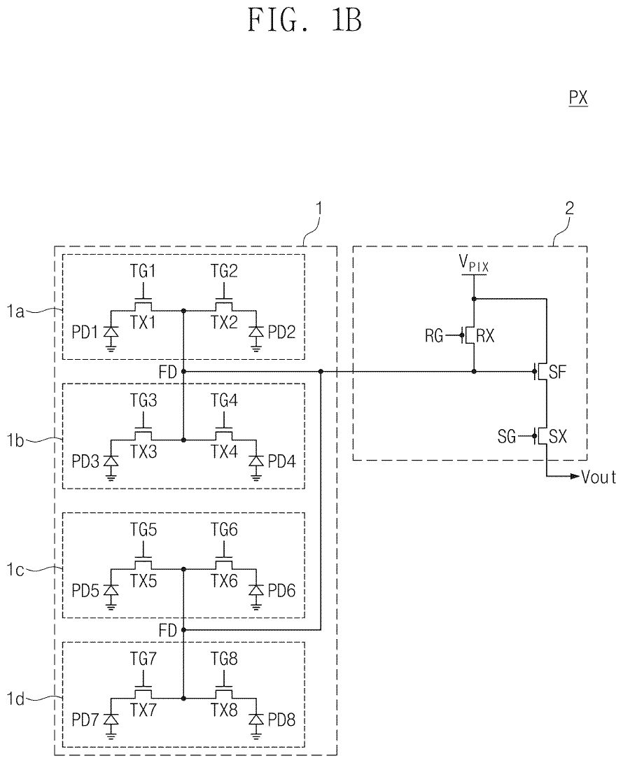

FIG. 1A is a circuit diagram illustrating a unit pixel of a pixel array according to an embodiment of the inventive concept. FIG. 1B is a circuit diagram illustrating a unit pixel of a pixel array according to an embodiment of the inventive concept.

Referring to FIGS. 1A and 1B, an image sensor may include a plurality of unit pixels, which are two-dimensionally arranged, and each unit pixel PX may be configured to convert optical signals to electrical signals.

The unit pixel PX may include a photoelectric conversion circuit 1 and a pixel circuit 2.

The photoelectric conversion circuit 1 may include a plurality of photoelectric conversion groups 1a, 1b, 1c, and 1d. The photoelectric conversion circuit 1 may include at least 4, 8, or 16 photoelectric conversion groups 1a, 1b, 1c, and 1d. Each of the photoelectric conversion groups 1a, 1b, 1c, and 1d may include at least two photoelectric conversion devices (e.g., photodiodes), a plurality of transfer transistors, and a floating diffusion region. Each of the photoelectric conversion groups 1a, 1b, 1c, and 1d may include 4, 8, or 16 photoelectric conversion devices.

In an embodiment, the photoelectric conversion circuit 1 may include first, second, third, and fourth photoelectric conversion groups 1a, 1b, 1c, and 1d.

The first photoelectric conversion group 1a may include a first photodiode PD1, a second photodiode PD2, a first transfer transistor TX1, and a second transfer transistor TX2. The first and second transfer transistors TX1 and TX2 may be configured to transfer the electric charges, which are accumulated in the first and second photoelectric conversion devices PD1 and PD2, to a floating diffusion region FD.

The second photoelectric conversion group 1b may include a third photodiode PD3, a fourth photodiode PD4, a third transfer transistor TX3, and a fourth transfer transistor TX4. The third and fourth transfer transistors TX3 and TX4 may be configured to transfer the electric charges, which are accumulated in the third and fourth photoelectric conversion devices PD3 and PD4, to the floating diffusion region FD. The third photoelectric conversion group 1c may include a fifth photodiode PD5, a sixth photodiode PD6, a fifth transfer transistor TX5, and a sixth transfer transistor TX6. The fifth and sixth transfer transistors TX5 and TX6 may be configured to transfer the electric charges, which are accumulated in the fifth and sixth photoelectric conversion devices PD5 and PD6, to the floating diffusion region FD. The fourth photoelectric conversion group 1d may include a seventh photodiode PD7, an eighth photodiode PD8, a seventh transfer transistor TX7, and an eighth transfer transistor TX8. The seventh and eighth transfer transistors TX7 and TX8 may be configured to transfer the electric charges, which are accumulated in the seventh and eighth photoelectric conversion devices PD7 and PD8, to the floating diffusion region FD.

The first to fourth photoelectric conversion groups 1a, 1b, 1c, and 1d may be commonly connected to the floating diffusion region FD. That is, the first to eighth transfer transistors TX1 to TX8 may be commonly connected to the floating diffusion region FD.

Each of the first to fourth photoelectric conversion groups 1a, 1b, 1c, and 1d is illustrated to include two photodiodes, but the inventive concept is not limited to this example. For example, each photoelectric conversion group may include 4 or 8 photodiodes.

The transfer gate electrodes TG1 to TG8 of the first to eighth transfer transistors TX1 to TX8 may be controlled by first to eighth charge transfer signals. In the present specification, the transfer gate electrode of each transfer transistor may have a dual vertical gate structure. The dual vertical gate structure may indicate a structure in which two vertical transfer gates are provided for one photodiode. The same transfer control signal may be applied to the two vertical transfer gates in the dual vertical gate structure.

The floating diffusion region FD may be configured to accumulate and store electric charges generated in, and transferred from, at least one of the first to eighth photodiodes PD1 to PD8. A source follower transistor SF may be controlled, depending on the amount of photocharges accumulated in the floating diffusion region FD.

The pixel circuit 2 may include a reset transistor RX, a source follower transistor SF, a selection transistor SX, and a dual conversion gain transistor DCX, as shown in FIG. 1A. Alternatively, the pixel circuit 2 may include the reset transistor RX, the source follower transistor SF, and the selection transistor SX, as shown in FIG. 1B.

In an embodiment, the number of the pixel transistors in the pixel circuit 2 is not limited thereto, and the number of the pixel transistors in each unit pixel PX may vary.

In detail, the reset transistor RX may periodically reset electric charges, which are accumulated in a charge detection node or the floating diffusion region FD according to a reset signal applied to a reset gate electrode RG. The reset transistor RX may be placed between the floating diffusion region FD and a pixel power.

If the reset transistor RX and the dual conversion gain transistor DCX are turned on, a power supply voltage V_{PIX} may be transferred to the floating diffusion region FD. Thus, the electric charges, which are accumulated in the floating diffusion region FD, may be discharged to reset the floating diffusion region FD.

The dual conversion gain transistor DCX may be placed between and connected to the floating diffusion region FD and the reset transistor RX. The dual conversion gain transistor DCX may be configured to vary the capacitance of the charge detection node or the floating diffusion region FD in response to a dual conversion gain control signal applied to a dual conversion gate DCG, thereby adjusting the conversion gain in the unit pixel PX.

In detail, during image capture, low-and high-intensity light may be incident on the pixel array, and here, the dual conversion gain transistor DCX may be turned on in high-intensity mode and turned off in low-intensity mode. By using the dual conversion gain transistor DCX, a difference in conversion gain between the high-and low-intensity modes may be achieved.

If the dual conversion gain transistor DCX is turned on, the capacitance of the floating diffusion region FD may be increased, thereby reducing the conversion gain, and if the dual conversion gain transistor DCX is turned off, the capacitance of the floating diffusion region FD may be decreased, thereby increasing the conversion gain.

In an embodiment, two or more dual conversion gain transistors DCX may be placed between and connected to the reset transistor RX and the floating diffusion region FD, and the conversion gain in the unit pixel PX may vary, depending on the number of the dual conversion gain transistors DCX.

The source follower transistor SF may be a source follower buffer amplifier, which produces a source-drain current in proportion to a charge amount of the floating diffusion region FD, which is input to a source follower gate electrode. The source follower transistor SF may amplify a change in electric potential of the floating diffusion region FD and may output the amplified signal to an output line Vout through the selection transistor SX.

The selection transistor SX may be used to select each row of the unit pixels PX for a read operation. If the selection transistor SX is turned on by a selection signal applied to a selection gate electrode SG, an electrical signal may be output from a source terminal of the source follower transistor SF to the output line Vout.

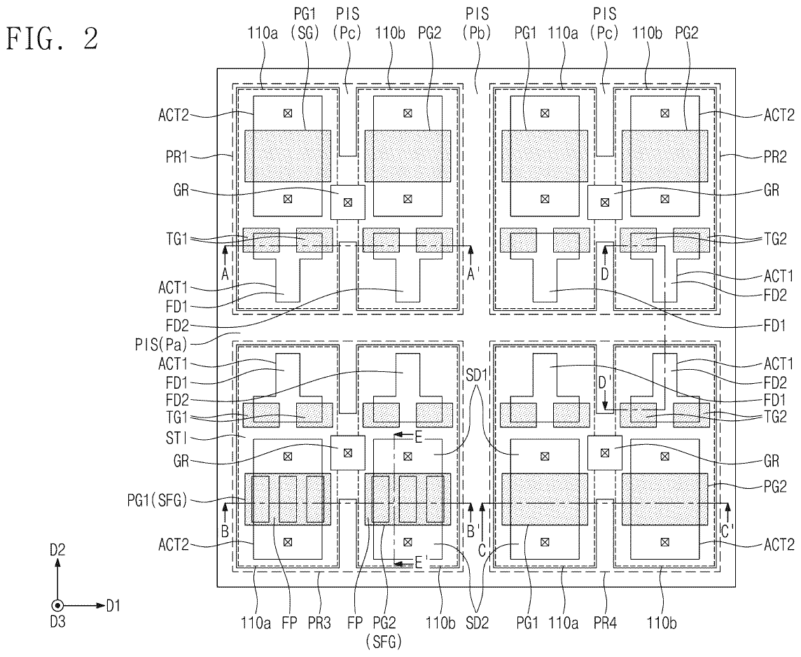

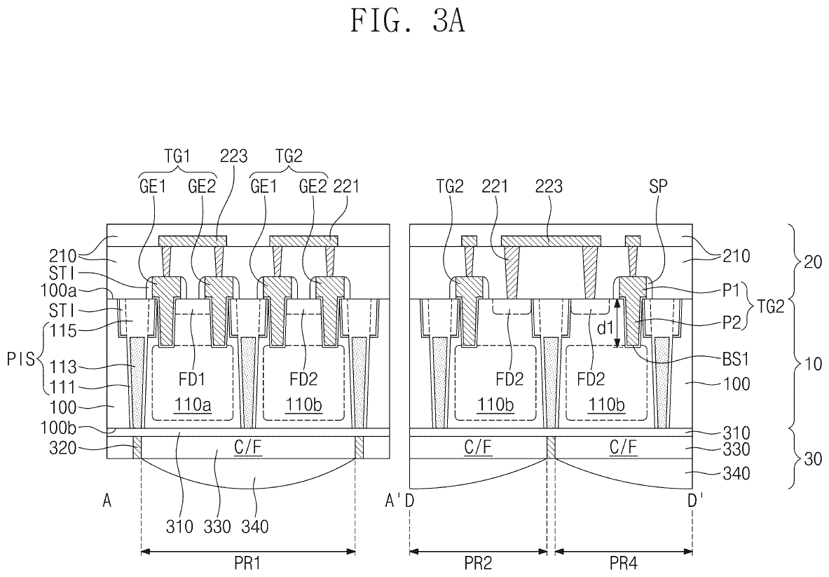

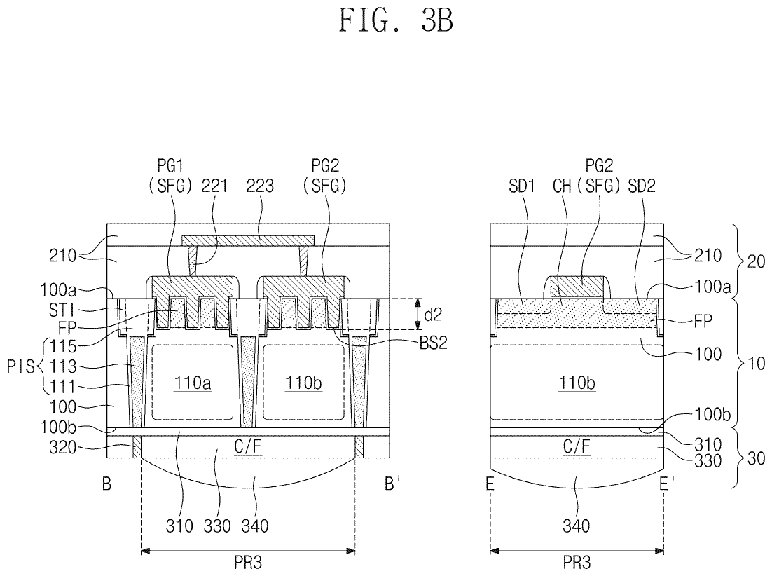

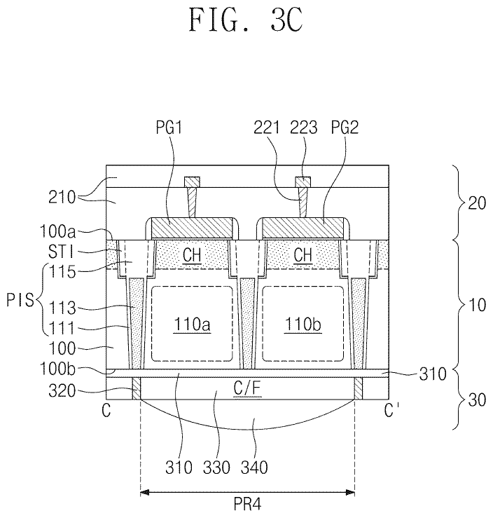

FIG. 2 is a plan view illustrating a unit pixel of an image sensor according to an embodiment of the inventive concept. FIG. 3A is a sectional view, which is taken along lines A-A′ and D-D′ of FIG. 2 to illustrate an image sensor according to an embodiment of the inventive concept. FIG. 3B is a sectional view, which is taken along lines B-B′ and E-E′ of FIG. 2 to illustrate an image sensor according to an embodiment of the inventive concept. FIG. 3C is a sectional view, which is taken along a line C-C′ of FIG. 2 to illustrate an image sensor according to an embodiment of the inventive concept.

Referring to FIGS. 2, 3A, 3B, and 3C, an image sensor according to an embodiment of the inventive concept may include a photoelectric conversion circuit layer 10, a pixel circuit layer 20, and an optically-transparent layer 30.

The photoelectric conversion circuit layer 10 may be disposed between the pixel circuit layer 20 and the optically-transparent layer 30, when viewed in a vertical section. The photoelectric conversion circuit layer 10 may include a semiconductor substrate 100, an isolation structure PIS, a shallow trench isolation pattern STI, photoelectric conversion regions 110a and 110b, transfer gate electrodes TG1, TG2, TG3, and TG4, and floating diffusion regions FD1 and FD2.

The pixel circuit layer 20 may include pixel circuits (e.g., MOS transistors), which are electrically connected to the floating diffusion regions FD1 and FD2. That is, the pixel circuit layer 20 may include the reset transistor RX, the selection transistor SX, the dual conversion gain transistor DCX, and the source follower transistor SF previously described with reference to FIGS. 1A and 1B and may include interconnection lines, which are connected to the pixel circuits 2 of FIGS. 1A and 1B.

The optically-transparent layer 30 may be configured to perform an operation of focusing and filtering light, which is incident from the outside, and to provide the light to the photoelectric conversion circuit layer 10. The optically-transparent layer 30 may include a planarization insulating layer 310, a grid 320, color filters 330, and micro lenses 340.

In detail, the semiconductor substrate 100 may have a first or top surface 100a and a second or bottom surface 100b which are opposite to each other. The semiconductor substrate 100 may be a substrate including a bulk silicon substrate and an epitaxial layer, which are sequentially stacked and are of a first conductivity type (e.g., p-type), and in the case where the bulk silicon substrate is removed during a fabrication process of an image sensor, the semiconductor substrate 100 may be composed of only the p-type epitaxial layer. In an embodiment, the semiconductor substrate 100 may be a bulk semiconductor substrate including a well of the first conductivity type.

The semiconductor substrate 100 may include a plurality of pixel regions PR1, PR2, PR3, and PR4 defined by the isolation structure PIS. The pixel regions PR1, PR2, PR3, and PR4 may be arranged in a first direction D1 and a second direction D2, which are not parallel to each other, or in a matrix shape. The pixel regions may include first, second, third, and fourth pixel regions PR1, PR2, PR3, and PR4, where the first and second pixel regions PR1 and PR2 are adjacent to each other in the first direction D1, and the first and third pixel regions PR1 and PR3 are adjacent to each other in the second direction D2. The second and fourth pixel regions PR2 and PR4 may be adjacent to each other in the second direction D2, and the second and third pixel regions PR2 and PR3 may be disposed in a diagonal direction that is oblique to the first and second directions D1 and D2. Here, the first and second directions D1 and D2 may be parallel to the first surface 100a of the semiconductor substrate 100 and may not be parallel to each other. A third direction D3 may be perpendicular to the first surface 100a of the semiconductor substrate 100.

Each of the first to fourth pixel regions PR1 to PR4 may be enclosed by the isolation structure PIS, when viewed in a plan view. Each of the first to fourth pixel regions PR1 to PR4 may be defined by a pair of first portions Pa, which are extended in the first direction D1, and a pair of second portions Pb, which are extended in the second direction D2. In each of the first to fourth pixel regions PR1 to PR4, the isolation structure PIS may include a pair of third portions Pc. The third portions Pc may be extended from the first portions Pa in the second direction D2 or may be extended from the second portions Pb in the first direction D1 and may be spaced apart from each other.

The isolation structure PIS may be provided to vertically penetrate the semiconductor substrate 100. In detail, the isolation structure PIS may have a length in a direction (e.g., the third direction D3), which is perpendicular to the top surface of the semiconductor substrate 100, and the length of the isolation structure PIS may be substantially equal to a vertical thickness of the semiconductor substrate 100. In an embodiment, the isolation structure PIS may be vertically extended from the first surface 100a of the semiconductor substrate 100 to the second surface 100b and may be spaced apart from the second surface 100b of the semiconductor substrate 100.

The isolation structure PIS may include a liner insulating pattern 111, a gap-fill pattern 113, and a capping insulating pattern 115. The gap-fill pattern 113 may be provided to vertically penetrate a portion of the semiconductor substrate 100, and the liner insulating pattern 111 may be provided between the gap-fill pattern 113 and the semiconductor substrate 100. The capping insulating pattern 115 may be disposed on the gap-fill pattern 113. The liner insulating pattern 111 and the capping insulating pattern 115 may be formed of or include at least one of silicon oxide, silicon oxynitride, or silicon nitride. The gap-fill pattern 113 may be formed of or include undoped poly-silicon or doped poly-silicon. The gap-fill pattern 113 may include an air gap or a void. The capping insulating pattern 115 of the isolation structure PIS may include the same insulating material as the shallow trench isolation pattern STI, and in this case, there may be no observable interface between the capping insulating pattern 115 and the shallow trench isolation pattern STI.

In an embodiment, the first and second photoelectric conversion regions 110a and 110b may be provided in the semiconductor substrate 100, in each of the first to fourth pixel regions PR1 to PR4. In the first and second photoelectric conversion regions 110a and 110b, light, which is incident from the outside, may be converted to electrical signals.

The first and second photoelectric conversion regions 110a and 110b may be impurity regions, which are doped with dopants having a second conductivity type (e.g., n-type) that is different from the first conductivity type of the semiconductor substrate 100. The semiconductor substrate 100 of the first conductivity type and the first and second photoelectric conversion regions 110a and 110b may constitute a pair of photodiodes. That is, the semiconductor substrate 100 of the first conductivity type and the first or second photoelectric conversion regions 110a or 110b may form junctions serving as the photodiodes. In the case where light is incident into the first and second photoelectric conversion regions 110a and 110b constituting the photodiode, photocharges may be generated and accumulated in proportion to an intensity of the incident light.

In each of the first to fourth pixel regions PR1 to PR4, there may be a phase difference between electrical signals that are respectively output from the first and second photoelectric conversion regions 110a and 110b. The image sensor may be configured to measure a distance to a target object, based on a difference in phase between the electrical signals, which are output from the paired photoelectric conversion regions (e.g., the first and second photoelectric conversion regions 110a and 110b), to examine whether the target object is in focus or the degree to which it is out of focus, and to automatically correct the focus of the image sensor based the examined result.

Each of the first and second photoelectric conversion regions 110a and 110b may have a first width in the first direction D1 and a first length, which is larger than the first width, the second direction D2. In an embodiment, the first length may be about 2 times the first width.

The first and second photoelectric conversion regions 110a and 110b may be spaced apart from each other in the first direction D1, with the third portions Pc of the isolation structure PIS interposed therebetween. The third portions Pc of the isolation structure PIS may reflect incident light physically at an edge portion of each of the first to fourth pixel regions PR1 to PR4, and in this case, it may be possible to reduce a cross-talk issue between the first and second photoelectric conversion regions 110a and 110b.

In each of the first to fourth pixel regions PR1 to PR4, the shallow trench isolation pattern STI may be disposed to be adjacent to the first surface 100a of the semiconductor substrate 100. A bottom surface of the shallow trench isolation pattern STI may be vertically spaced apart from the first and second photoelectric conversion regions 110a and 110b.

The shallow trench isolation pattern STI may be formed in a trench which is formed by recessing the first surface 100a of the semiconductor substrate 100. The shallow trench isolation pattern STI may be formed of or include an insulating material.

Referring to FIGS. 3B, 4, and 5, the shallow trench isolation pattern STI may include a liner insulating layer, which is formed to conformally cover a surface of the trench, and an insulating gap-fill layer, which is formed to fill the trench covered with the liner insulating layer. The insulating gap-fill layer may include at least one of a silicon oxide layer, a silicon oxynitride layer, or a silicon nitride layer.

In an embodiment, the shallow trench isolation pattern STI may be provided to define first and second active portions ACT1 and ACT2, in each of the first to fourth pixel regions PR1 to PR4. The first and second active portions ACT1 and ACT2 may be portions of the semiconductor substrate 100. When viewed in a plan view, the first and second active portions ACT1 and ACT2 may be overlapped with each of the first and second photoelectric conversion regions 110a and 110b. That is, two first active portions ACT1 and two second active portions ACT2 may be provided in each of the pixel regions PR1 to PR4, but the inventive concept is not limited to this example.

The first and second active portions ACT1 and ACT2 may be spaced apart from each other in the second direction D2 by the shallow trench isolation pattern STI and may have different sizes and shapes from each other. The first active portion ACT1 may have a T shape, but the inventive concept is not limited to this example; for example, it may have a tetragonal or a polygonal shape. The second active portion ACT2 may have a long axis in the second direction D2 and a short axis in the first direction D1. Each of the second active portion ACT2 may have a second length that is smaller than the first length of the first or second photoelectric conversion region 110a or 110b, when measured in the second direction D2.

The first and second active portions ACT1 and ACT2 in the third and fourth pixel regions PR3 and PR4 may be disposed with mirror symmetry relative to the first and second active portions ACT1 and ACT2 in the first and second pixel regions PR2 and PR4.

The first and second transfer gate electrodes TG1 and TG2 may be provided on each of the first to fourth pixel regions PR1 to PR4.

The first transfer gate electrode TG1 may be disposed on the first active portion ACT1 and may be overlapped with the first photoelectric conversion region 110a. The second transfer gate electrode TG2 may be disposed on the first active portion ACT1 and may be overlapped with the second photoelectric conversion region 110b.

Each of the first and second transfer gate electrodes TG1 and TG2 may include a portion that is disposed in a trench formed by recessing the first surface 100a of the semiconductor substrate 100. In an embodiment, each of the first and second transfer gate electrodes TG1 and TG2 may include a first portion P1, which is disposed on the first surface 100a of the semiconductor substrate 100, and a second portion P2, which is vertically extended from the first portion P1 into the semiconductor substrate 100. Each of the first and second transfer gate electrodes TG1 and TG2 may have a first bottom surface BS1, which is placed at a level lower than the first surface 100a of the semiconductor substrate 100.

In an embodiment, each of the first and second transfer gate electrodes TG1 and TG2 may have a dual gate electrode structure, in which a pair of first and second vertical gates GE1 and GE2 are provided on each of the first active portions ACT1. In an embodiment, the shape and positions of the first and second transfer gate electrodes TG1 and TG2 may be variously changed. In each of the first and second transfer gate electrodes TG1 and TG2, a pair of the first and second vertical gates GE1 and GE2 may be electrically connected to each other through a metal line 223.

In an embodiment, the first and second transfer gate electrodes TG1 and TG2 may be formed of a conductive layer containing dopants of the same conductivity type as the semiconductor substrate 100. As an example, the first and second transfer gate electrodes TG1 and TG2 may be formed of or include polysilicon that is doped with dopants of the first conductivity type (e.g., p-type).

A gate insulating layer with a uniform thickness may be interposed between the first and second transfer gate electrodes TG1 and TG2 and the semiconductor substrate 100. Insulating spacers SP may be disposed on opposite side surfaces of the first and second transfer gate electrodes TG1 and TG2.

In each of the first to fourth pixel regions PR1 to PR4, the first floating diffusion region FD1 may be provided in the first active portion ACT1 between the first transfer gate electrodes TG1. The second floating diffusion region FD2 may be provided in the first active portion ACT1 between the second transfer gate electrodes TG2.

The first and second floating diffusion regions FD1 and FD2 may be formed through a doping process of injecting dopants of the second conductivity type, which is different from that of the semiconductor substrate 100, into the semiconductor substrate 100. For example, the first and second floating diffusion regions FD1 and FD2 may be n-type doping regions.

The first and second floating diffusion regions FD1 and FD2 in the first to fourth pixel regions PR1 to PR4 may be electrically connected to each other through contact plugs 221 and the metal line 223. The first and second floating diffusion regions FD1 and FD2 in the first to fourth pixel regions PR1 to PR4 may electrically and commonly connected to the pixel transistors SF, DCX, RX, and SX described with reference to FIGS. 1A and 1B.

In each of the first to fourth pixel regions PR1 to PR4, first and second pixel gate electrodes PG1 and PG2 may be disposed on the second active portions ACT2, respectively. In each of the first, second, and fourth pixel regions PR1, PR2, and PR4, the first pixel gate electrode PG1 may be overlapped with the first photoelectric conversion region 110a, and the second pixel gate electrode PG2 may be overlapped with the second photoelectric conversion region 110b.

In each of the first to fourth pixel regions PR1 to PR4, the first and second pixel gate electrodes PG1 and PG2 may constitute one of the pixel transistors (e.g., the reset, source follower, dual conversion gain, and selection transistors RX, SF, DCX, and SX) described with reference to FIGS. 1A and 1B.

The first pixel gate electrode PG1 on the first pixel region PR1 may be provided as a selection gate electrode of the selection transistor SX described with reference to FIGS. 1A and 1B, and first and second pixel gate electrodes PG1(SFG) and PG21(SFG) on the third pixel region PR3 may be provided as a source follower gate electrode of the source follower transistor SF described with reference to FIGS. 1A and 1B. The first and second pixel gate electrodes PG1(SFG) and PG21(SFG) on the third pixel region PR may be electrically connected to each other through the metal line 223.

The first pixel gate electrode PG1 on the fourth pixel region PR4 may be provided as a dual conversion gain gate electrode of the dual conversion gain transistor DCX described with reference to FIGS. 1A and 1B. The second pixel gate electrode PG2 on the fourth pixel region PR4 may be provided as a reset gate electrode of the reset transistor RX described with reference to FIGS. 1A and 1B. Alternatively, both of the first and second pixel gate electrodes PG1 and PG2 on the fourth pixel region PR4 may be provided as a reset gate electrode of the reset transistor RX.

In addition, the first and second pixel gate electrodes PG1 and PG2 on the second pixel region PR2 may be used as one of the pixel transistors constituting the unit pixel and may be provided as a dummy gate. In an embodiment, the functions of the first and second pixel gate electrodes PG1 and PG2 on the first to fourth pixel regions PR1 to PR4 may be variously changed.

In the first to fourth pixel regions PR1 to PR4, the first and second pixel gate electrodes PG1 and PG2 may be formed of a conductive layer containing dopants of the same conductivity type as the semiconductor substrate 100. The first and second pixel gate electrodes PG1 and PG2 may be formed of or include polysilicon that is doped with dopants of the first conductivity type (e.g., p-type).

Since the first and second pixel gate electrodes PG1 and PG2 include dopants of the first conductivity type, the threshold voltage of the pixel transistors SF, RX, DCX, and SX may be increased. Accordingly, the linearity in the output characteristics of the source follower transistor SF may be improved under low-light conditions, and the leakage current characteristics of the source follower transistor SF may also be improved.

The insulating spacers SP may be disposed on opposite side surfaces of the first and second pixel gate electrodes PG1 and PG2. The insulating spacers SP may be formed of or include at least one of silicon oxide, silicon nitride, silicon oxynitride, silicon carbon nitride (SiCN), or silicon carbon oxynitride (SiCON).

A first source/drain region SD1 may be provided in the second active portions ACT2 on one side of each of the first and second pixel gate electrodes PG1 and PG2, and second source/drain regions SD2 may be provided in the second active portions ACT2 on the opposite side of each of the first and second pixel gate electrodes PG1 and PG2.

The first and second source/drain regions SD1 and SD2 may be formed through a doping process of injecting dopants of the second conductivity type, which is different from that of the semiconductor substrate 100, into the semiconductor substrate 100. Each of the first and second source/drain regions SD1 and SD2 may be, for example, an n-type doping region.

In an embodiment, at least one of the pixel transistors SF, DCX, RX, and SX, which constitute the unit pixel PX of FIGS. 1A and 1B, may include fin active patterns FP between the first and second pixel gate electrodes PG1 and PG2 and the second active portions ACT2.

In the third pixel region PR3, the source follower transistor SF of FIGS. 1A and 1B may be provided on the second active portions ACT2, and the fin active patterns FP may vertically protrude from each of the second active portions ACT2. The fin active patterns FP may be portions of the semiconductor substrate 100 and may be formed by patterning a portion of the semiconductor substrate 100.

In detail, top surfaces of the fin active patterns FP may be placed at substantially the same level as the first surface 100a of the semiconductor substrate 100. The fin active patterns FP may be disposed between the first and second source drain regions SD1 and SD2. The fin active patterns FP may have a bar shape extended in the second direction D2.

Each of the first and second pixel gate electrodes PG1(SFG) and PG2(SFG) on the third pixel region PR3 may be provided to enclose a top surface and opposite side surfaces of each of the fin active patterns FP. The gate insulating layers may be respectively interposed between the first and second pixel gate electrodes PG1 and PG2 and the fin active patterns FP.

In the third pixel region PR3, since the fin active patterns FP are provided on the second active portions ACT2, it may be possible to secure an effective channel width of the pixel transistors (e.g., the source follower transistor) in the first direction D1 and to secure an effective channel length in the second direction D2. Thus, even when the area of each pixel region PR is reduced, it may be possible to increase or optimize the electric characteristics of the pixel transistors.

In an embodiment, the fin active pattern FP may include a channel region CH that is doped with dopants of the second conductivity type. The channel region CH may be provided between the first and second source/drain regions SD1 and SD2. The concentration of the dopants of the second conductivity type in the channel region CH may be lower than the concentration of dopants of the second conductivity type in the first and second source/drain regions SD1 and SD2. Meanwhile, the channel region CH of the fin active patterns FP may be undoped with the dopants, and the channel region of the pixel transistor in the third pixel region PR3 may have the first conductivity type.

Since the channel region CH and the first and second source/drain regions SD1 and SD2 have the same conductivity type, a pixel transistor, which is composed of the first and second pixel gate electrodes PG1 and PG2 and the fin active patterns FP, may form a junction-less transistor. Thus, it may be possible to limit and/or prevent a junction leakage current from occurring between the channel region CH and the first and second source/drain regions SD1 and SD2.

Between the fin active patterns FP, each of the first and second pixel gate electrodes PG1(SFG) and PG2(SFG) on the third pixel region PR3 may have a second bottom surface BS2 placed at a level lower than the first surface 100a of the semiconductor substrate 100. In addition, the second bottom surfaces BS2 of the first and second pixel gate electrodes PG1(SFG) and PG2(SFG) may be placed at a level higher than the first bottom surfaces BS1 of the first and second transfer gate electrodes TG1 and TG2. That is, each of the first and second pixel gate electrodes PG1(SFG) and PG2(SFG) on the third pixel region PR3 may have the second bottom surface BS2, which is placed at a level between the first surface 100a of the semiconductor substrate 100 and the first bottom surface. Furthermore, when measured from the first surface 100a of the semiconductor substrate 100, a vertical length d1 of the first and second transfer gate electrodes TG1 and TG2 may be larger than a vertical length d2 of the first and second pixel gate electrodes PG1(SFG) and PG2(SFG).

In an embodiment, the first and second pixel gate electrodes PG1 and PG2, which are provided on the first, second, and fourth pixel regions PR1, PR2, and PR4 but not the third pixel region PR3, may have bottom surfaces that are parallel to the first surface 100a of the semiconductor substrate 100. That is, the pixel transistors, which are provided in the first, second, and fourth pixel regions PR1, PR2, and PR4, may be planar-type MOS transistors.

The first and second pixel gate electrodes PG1 and PG2 on the first, second, and fourth pixel regions PR1, PR2, and PR4 may be disposed on the channel region CH that contains the dopants of the second conductivity type. Alternatively, the pixel transistors on the first, second, and fourth pixel regions PR1, PR2, and PR4 may be provided on the semiconductor substrate 100 of the first conductivity type. Each of the pixel transistors on the first, second, and fourth pixel regions PR1, PR2, and PR4 may include a channel region of the first conductivity type.

Furthermore, in each of the first to fourth pixel regions PR1 to PR4, a ground impurity region GR may be provided between the first and second photoelectric conversion regions 110a and 110b. The ground impurity region GR may be provided between the third portions Pc of the isolation structure PIS. The ground impurity region GR may be formed by doping dopants of the same conductivity type (e.g., the first conductivity type) as the semiconductor substrate 100.

Interlayer insulating layers 210 may be stacked on the first surface 100a of the semiconductor substrate 100, and the interlayer insulating layers 210 may be provided to cover the pixel transistors RX, SF, DCX, and SX, which constitute readout circuits, and the first and second transfer gate electrodes TG1 and TG2. The interlayered insulating layers 210 may be formed of or include at least one of, for example, silicon oxide, silicon nitride, or silicon oxynitride.

An interconnection structure, which is connected to the readout circuits, may be disposed in the interlayer insulating layers 210. The interconnection structure may include metal lines 223 and contact plugs 221 connecting them to each other.

Referring to FIGS. 3A, 3B, and 3C, the optically-transparent layer 30 may be disposed on the second surface 100b of the semiconductor substrate 100.

The planarization insulating layer 310 may cover the second surface 100b of the semiconductor substrate 100. The planarization insulating layer 310 may be formed of a transparent insulating material and may include a plurality of layers. The planarization insulating layer 310 may be formed of an insulating material whose refractive index is different from the semiconductor substrate 100. The planarization insulating layer 310 may include at least one of metal oxide and/or silicon oxide.

The grid 320 may be disposed on the planarization insulating layer 310. When viewed in a plan view, the grid 320 may have a grid shape, similar to the isolation structure PIS. The grid 320 may be overlapped with the isolation structure PIS, when viewed in a plan view. That is, the grid 320 may include first portions, which are extended in the first direction D1, and second portions, which are extended in the second direction D2 to cross the first portions. A width of the grid 320 may be substantially equal to or smaller than the smallest width of the isolation structure PIS.

The grid 320 may include a conductive pattern and/or a low refractive pattern. The conductive pattern may be formed of or include at least one of metallic materials (e.g., titanium, tantalum, or tungsten). The low refractive pattern may be formed of or include a material whose refractive index is lower than the conductive pattern. The low refractive pattern may be formed of an organic material and may have a refractive index of about 1.1 to 1.3. For example, the grid 320 may be a polymer layer, in which silica nano-particles are included.

The color filter 330 may be formed to correspond to each of the pixel regions PR1 to PR4. The color filters 330 may fill a space defined by the grid 320. The color filters 330 may include red, green, or blue color filters, or magenta, cyan, or yellow color filters, depending on the unit pixel. As another example, some of the color filters 330 may include a white color filter or an infrared light filter.

The micro lenses 340 may be disposed on the color filters 330. The micro lenses 340 may have a convex shape and may have a specific curvature radius. The micro lenses 340 may be formed of or include an optically transparent resin. The micro lenses 340 may be disposed on the color filters 330 to correspond to the pixel regions PR, respectively. In an embodiment, at least one of the micro lenses 340 may be commonly disposed on at least two pixel regions PR.

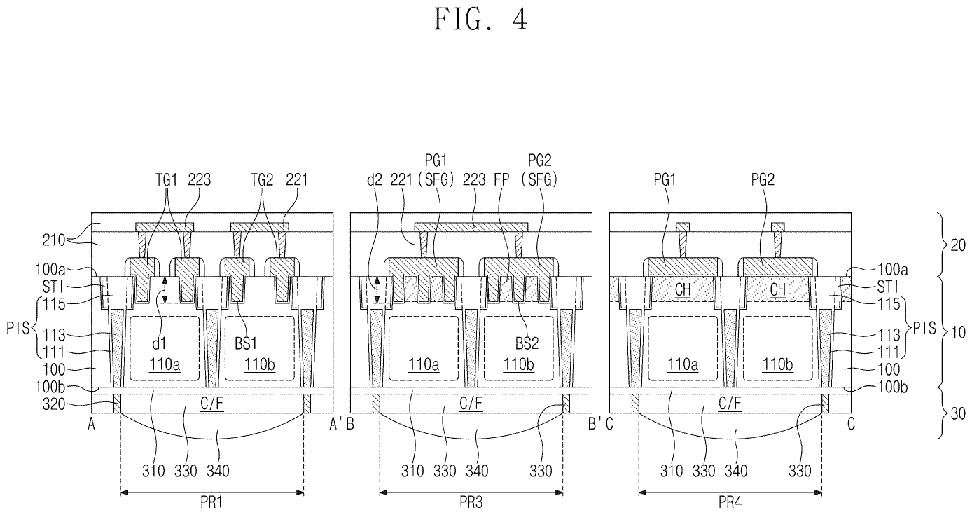

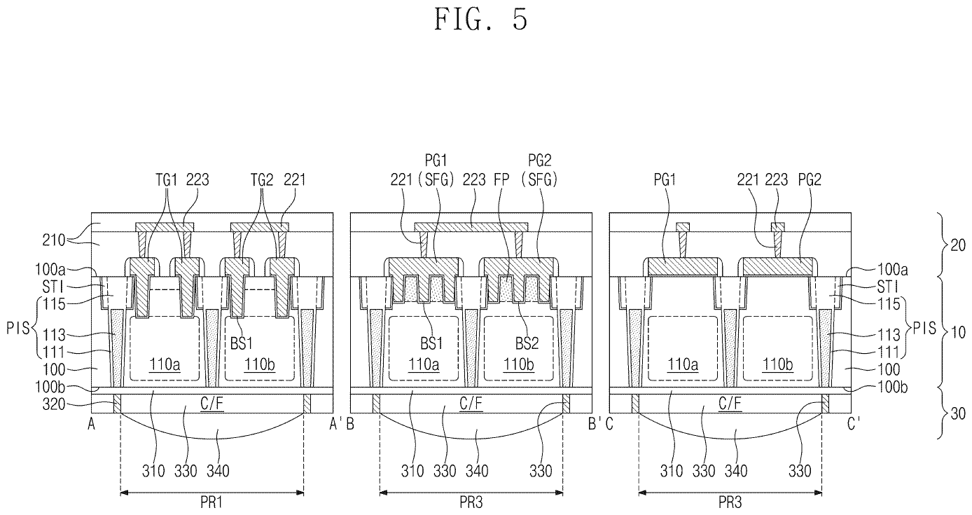

FIGS. 4 and 5 are sectional views, which are taken along the lines A-A′, B-B′, and C-C′ of FIG. 2 to illustrate an image sensor according to an embodiment of the inventive concept. For concise description, the same element in the image sensor described with reference to FIGS. 2, 3A, 3B, and 3C may be identified by the same reference number without repeating an overlapping description thereof.

Referring to FIG. 4, the first bottom surfaces BS1 of the first and second transfer gate electrodes TG1 and TG2 may be placed at substantially the same level as the second bottom surfaces BS2 of the first and second pixel gate electrodes PG1(SFG) and PG2(SFG), which are provided in the third pixel region PR3, unlike the previous embodiment. In other words, the first and second bottom surfaces BS1 and BS2 may be placed at levels that are spaced apart from the first surface 100a of the semiconductor substrate 100 by the same distance. That is, when measured from the first surface 100a of the semiconductor substrate 100, the vertical length d1 of the first and second transfer gate electrodes TG1 and TG2 may be substantially the same as the vertical length d2 of the first and second pixel gate electrodes PG1(SFG) and PG2(SFG).

The first and second transfer gate electrodes TG1 and TG2 and the first and second pixel gate electrodes PG1 and PG2 on the first to fourth pixel regions PR1 to PR4 may be formed at the same time and may be formed of or include the same conductive material. In an embodiment, the first and second transfer gate electrodes TG1 and TG2 and the first and second pixel gate electrodes PG1 and PG2 on the first to fourth pixel regions PR1 to PR4 may be formed of or include polysilicon that is doped with dopants of the first conductivity type (e.g., p-type).

Furthermore, the channel region CH, which is doped with dopants of the second conductivity type (e.g., n-type), may be provided below the first and second pixel gate electrodes PG1 and PG2 on the first to fourth pixel regions PR1 to PR4.

Referring to FIG. 5, the pixel transistor on the third pixel region PR3 may include the first and second pixel gate electrodes PG1 and PG2, which are disposed on the channel region CH doped with dopants of the second conductivity type (e.g., n-type).

Planar-type pixel transistors may be provided in the first, second, and fourth pixel regions PR1, PR2, and PR4, and the semiconductor substrate 100 of the first conductivity type may be used as channel regions of the pixel transistors on the first, second, and fourth pixel regions PR1, PR2, and PR4, respectively. In the first, second, and fourth pixel regions PR1, PR2, and PR4, each of the first and second pixel gate electrodes PG1 and PG2 may have a bottom surface parallel to the first surface 100a of the semiconductor substrate 100.

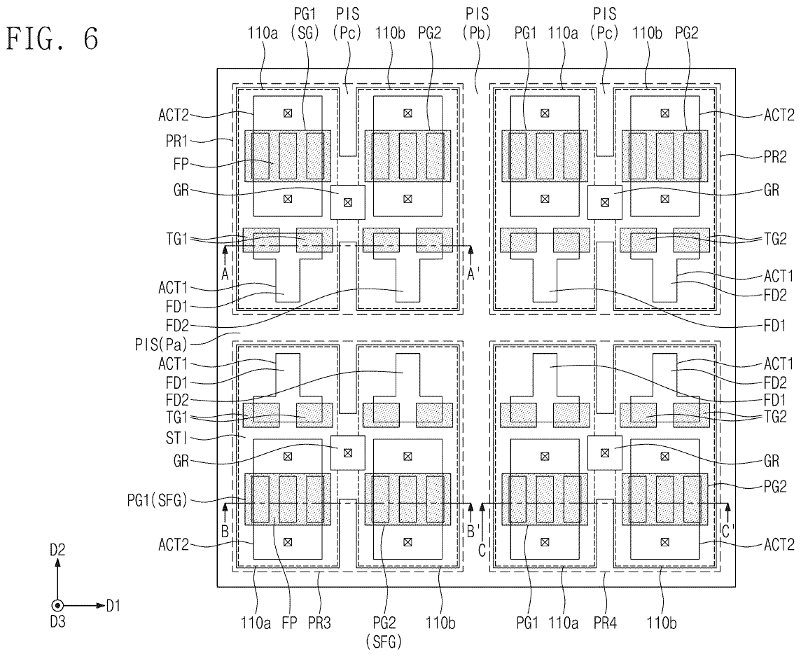

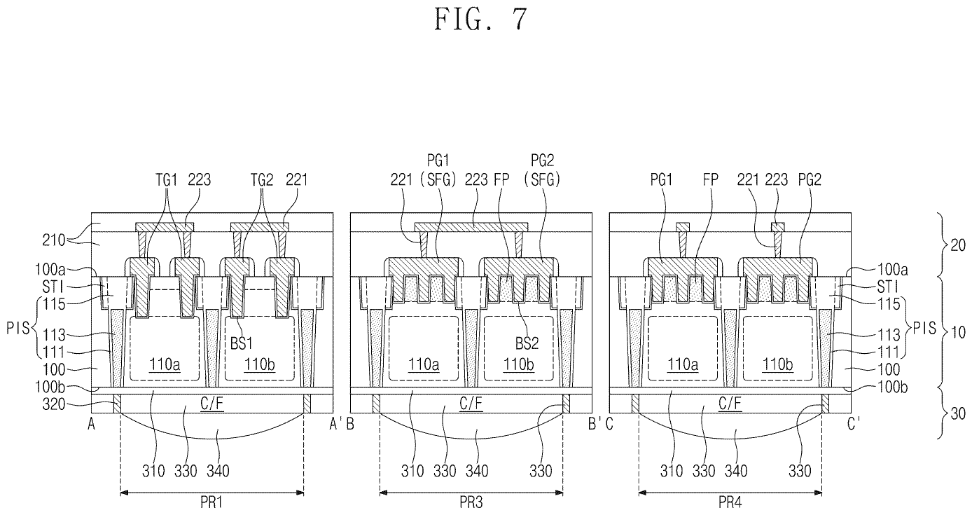

FIG. 6 is a plan view illustrating a unit pixel of an image sensor according to an embodiment of the inventive concept. FIG. 7 is a sectional view, which is taken along lines A-A′, B-B′, and C-C′ of FIG. 6 to illustrate an image sensor according to an embodiment of the inventive concept. For concise description, the same element in the image sensor described with reference to FIGS. 2, 3A, 3B, and 3C may be identified by the same reference number without repeating an overlapping description thereof.

Referring to FIGS. 6 and 7, all of the pixel transistors on the first to fourth pixel regions PR1 to PR4 may be fin-type MOS transistors.

In each of the first to fourth pixel regions PR1 to PR4, the fin active patterns FP may be provided between the second active portions ACT2 and the first and second pixel gate electrodes PG1 and PG2.

Each of the fin active patterns FP may vertically protrude from the second active portion ACT2. Each of the first and second pixel gate electrodes PG1 and PG2 may have a bottom surface placed at a level lower than the first surface 100a of the semiconductor substrate 100, between the fin active patterns FP.

In at least one of the first to fourth pixel regions PR1 to PR4, the fin active patterns FP may be doped with dopants of the second conductivity type. In an embodiment, in all of the first to fourth pixel regions PR1 to PR4, the fin active patterns FP may be doped with dopants of the second conductivity type. In another embodiment, the fin active patterns FP in the third pixel region PR3 may be doped with dopants of the second conductivity type, and the fin active patterns FP in the first, second, and fourth pixel regions PR1, PR2, and PR4 may be undoped with dopants of the second conductivity type. That is, the pixel transistor on the third pixel region PR3 may include a channel region of the second conductivity type, and each of the pixel transistors on the first, second, and fourth pixel regions PR1, PR2, and PR4 may include a channel region of the first conductivity type.

In another embodiment, the fin active patterns FP in the third pixel region PR3 may be undoped with dopants of the second conductivity type, and the fin active patterns FP in the first, second, and fourth pixel regions PR1, PR2, and PR4 may be doped with dopants of the second conductivity type. That is, the pixel transistor on the third pixel region PR3 may include a channel region of the first conductivity type, and each of the pixel transistors on the first, second, and fourth pixel regions PR1, PR2, and PR4 may include a channel region of the second conductivity type.

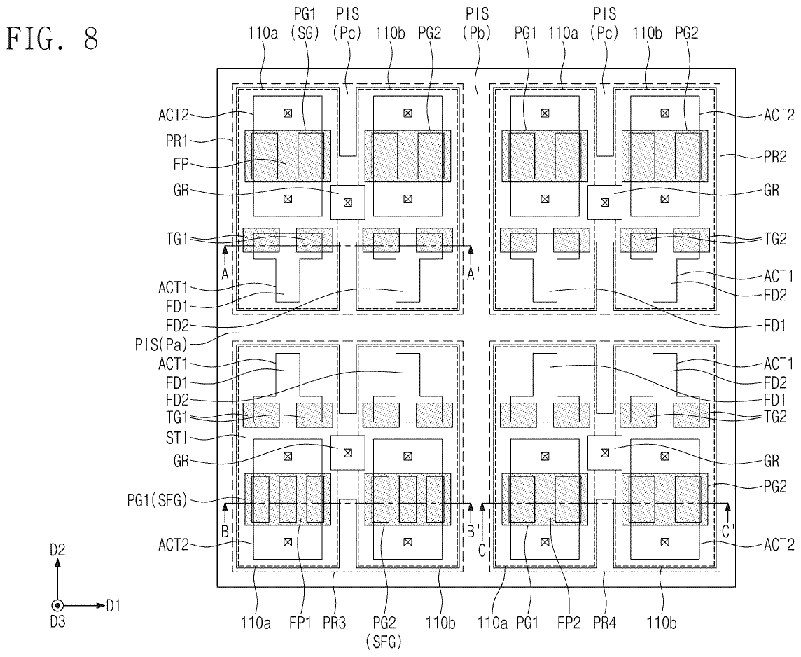

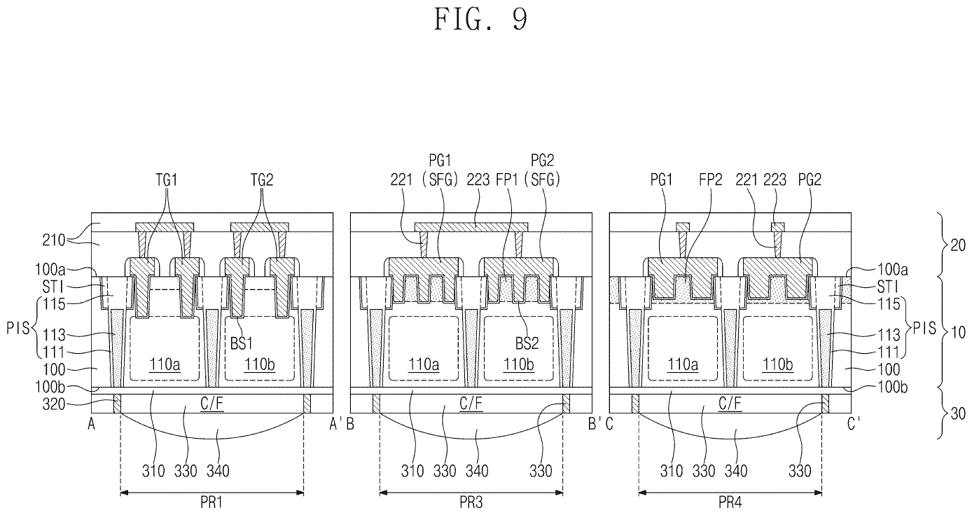

FIG. 8 is a plan view illustrating a unit pixel of an image sensor according to an embodiment of the inventive concept. FIG. 9 is a sectional view, which is taken along lines A-A′, B-B′, and C-C′ of FIG. 8 to illustrate an image sensor according to an embodiment of the inventive concept. For concise description, the same element in the image sensor described with reference to FIGS. 6 and 7 may be identified by the same reference number without repeating an overlapping description thereof.

Referring to FIGS. 8 and 9, all of the pixel transistors on the first to fourth pixel regions PR1 to PR4 may be fin-type MOS transistors, and the widths of the fin active patterns FP1 and FP2 may vary depending on the pixel transistors provided in the first to fourth pixel regions PR1 to PR4.

In the third pixel region PR3, a first fin active patterns FP1 may be provided between the second active portions ACT2 and the first and second pixel gate electrodes PG1 and PG2, and in the first, second, and fourth pixel regions PR1, PR2, and PR4, a second fin active patterns FP2 may be provided between the second active portions ACT2 and the first and second pixel gate electrodes PG1 and PG2. In the third pixel region PR3, each of the first and second pixel gate electrodes PG1 and PG2 may be disposed to cross the first fin active patterns FP1. In each of the first, second, and fourth pixel regions PR1, PR2, and PR4, each of the first and second pixel gate electrodes PG1 and PG2 may be disposed to cross the second fin active patterns FP2. In an embodiment, when measured in the first direction D1, a width of each of the first fin active patterns FP1 may be smaller than a width of each of the second fin active patterns FP2.

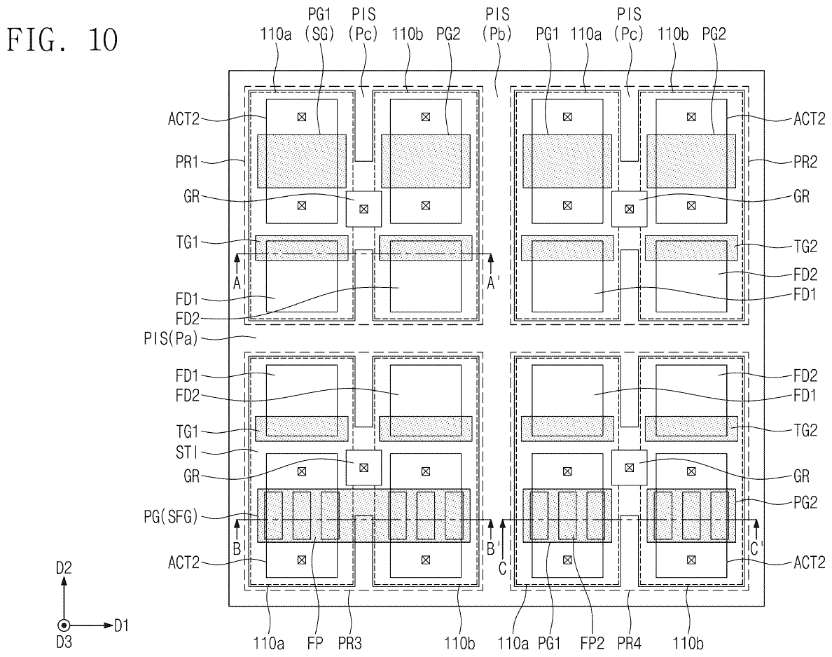

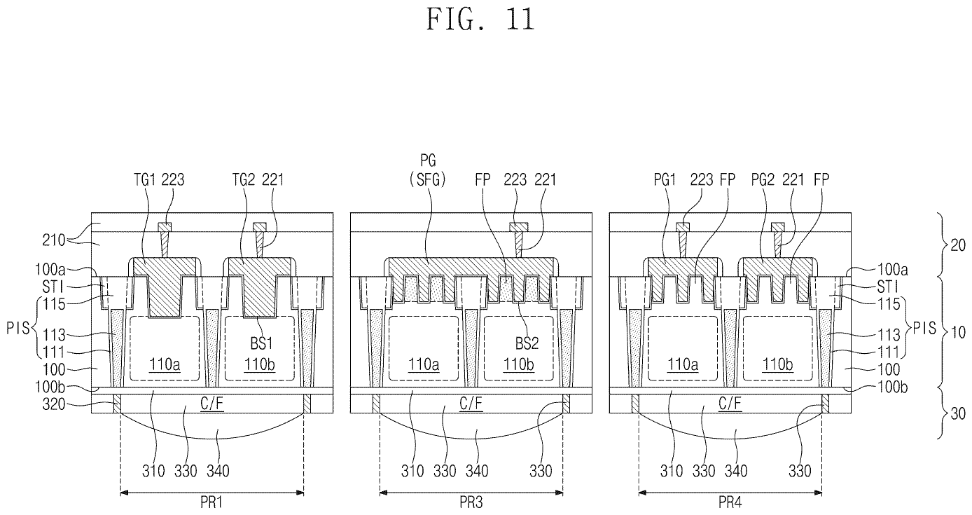

FIG. 10 is a plan view illustrating a unit pixel of an image sensor according to an embodiment of the inventive concept. FIG. 11 is a sectional view, which is taken along lines A-A′, B-B′, and C-C′ of FIG. 10 to illustrate an image sensor according to an embodiment of the inventive concept.

Referring to FIGS. 10 and 11, in each of the first to fourth pixel regions PR1 to PR4, the first and second transfer gate electrodes TG1 and TG2 may be provided on the first active portions ACT1, as described above, and each of the first and second transfer gate electrodes TG1 and TG2 may include a single vertical portion extended into the semiconductor substrate 100.

In each of the first, second, and fourth pixel regions PR1, PR2, and PR4, the first and second pixel gate electrodes PG1 and PG2 may be disposed on the second active portions ACT2, respectively. In the third pixel region PR3, one pixel gate electrode PG(SFG) may be disposed to cross the second active portions ACT2.

In the third pixel region PR3, the pixel gate electrode PG(SFG) may be longer than the first and second pixel gate electrodes PG1 and PG2 in the first direction D1. That is, the pixel gate electrode PG(SFG) may be overlapped with portions of the first and second photoelectric conversion regions 110a and 110b in the third pixel region PR3.

In the third and fourth pixel regions PR3 and PR4, the fin active patterns FP may be provided between the pixel gate electrode PG(SFG) and the second active portions ACT2.

The fin active patterns FP in the third pixel region PR3 may be doped with dopants of the second conductivity type, and the fin active patterns FP in the fourth pixel region PR4 may be undoped with dopants of the second conductivity type.

Alternatively, the channel regions of the pixel transistors on the first to fourth pixel regions PR1 to PR4 may be undoped with dopants of the second conductivity type. That is, each of the pixel transistors on the first to fourth pixel regions PR1 to PR4 may include a channel region of the first conductivity type.

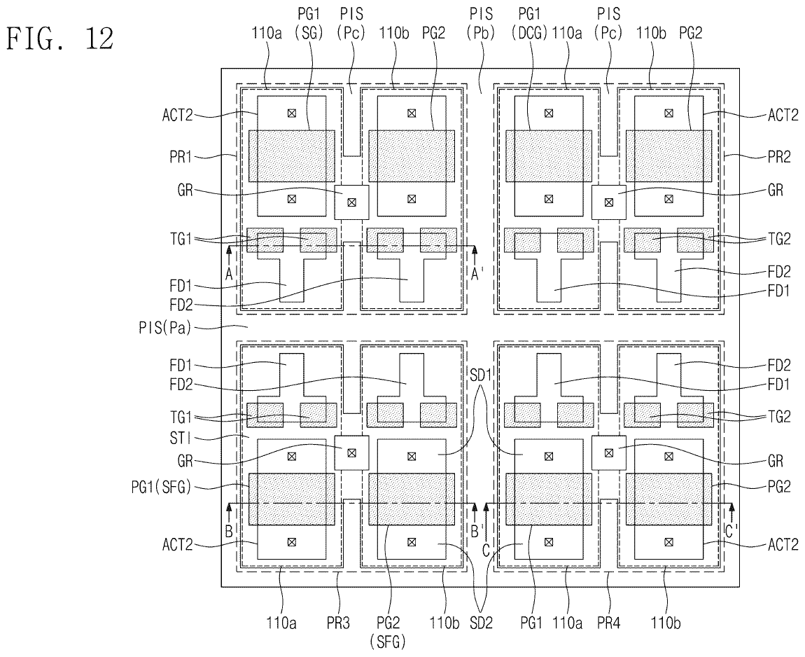

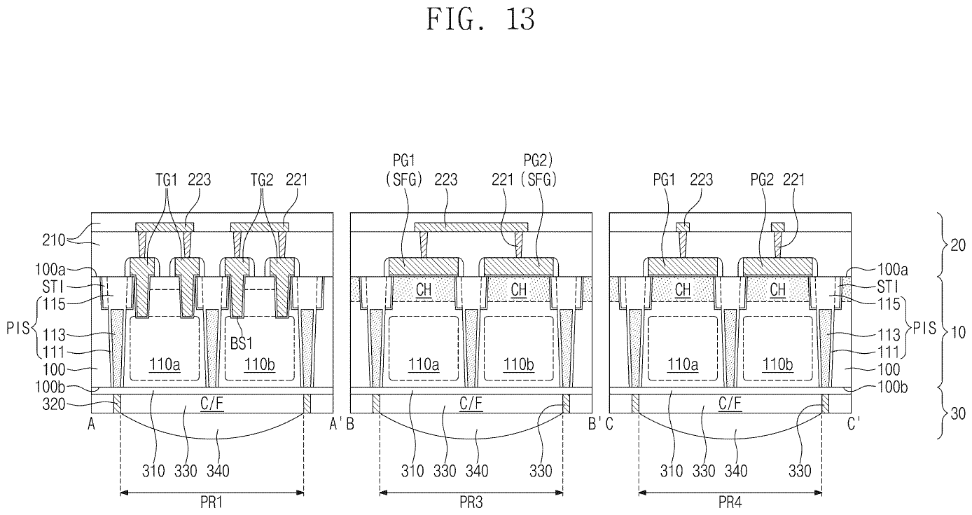

FIG. 12 is a plan view illustrating a unit pixel of an image sensor according to an embodiment of the inventive concept. FIG. 13 is a sectional view, which is taken along lines A-A′, B-B′, and C-C′ of FIG. 12 to illustrate an image sensor according to an embodiment of the inventive concept.

Referring to FIGS. 12 and 13, all of the pixel transistors on the first to fourth pixel regions PR1 to PR4 may be planar-type MOS transistors, and the first and second pixel gate electrodes PG1 and PG2 of the pixel transistors may include polysilicon containing dopants of the first conductivity type. Thus, the threshold voltage of the pixel transistors on the first to fourth pixel regions PR1 to PR4 may be increased.

In addition, the channel region CH between the first and second source/drain regions SD1 and SD2 may include dopants of the second conductivity type. The threshold voltage of each of pixel transistors may be adjusted depending on the concentration of the second conductivity-type dopants present in the channel region CH.

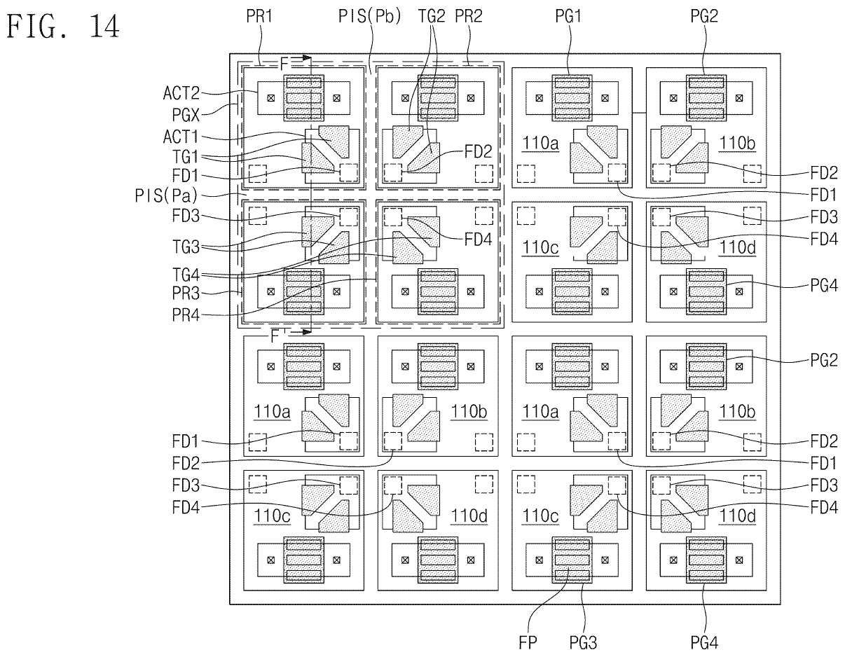

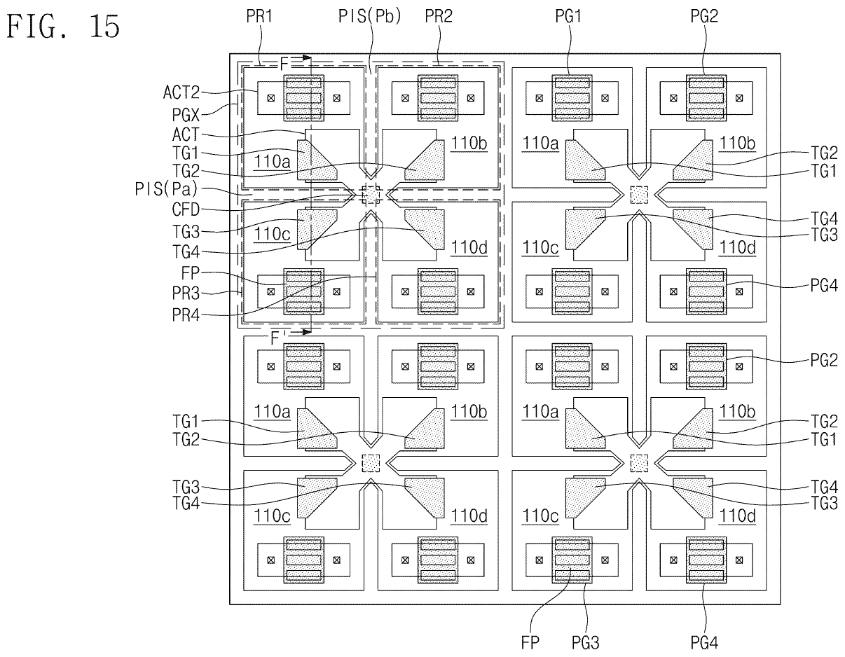

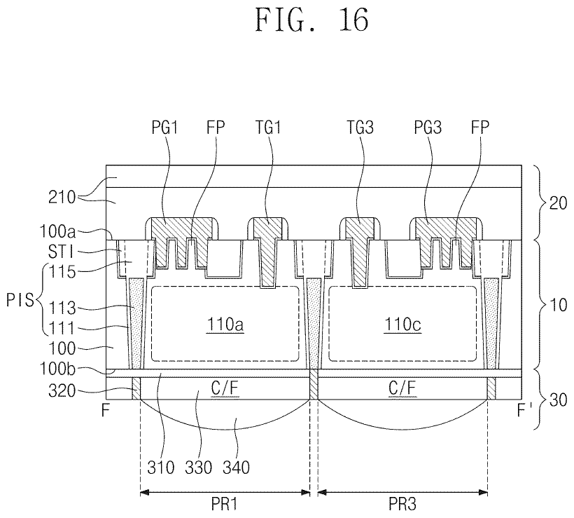

FIGS. 14 and 15 are plan views illustrating a unit pixel of an image sensor according to an embodiment of the inventive concept. FIG. 16 is a sectional view, which is taken along lines F-F′ of FIGS. 14 and 15 to illustrate an image sensor according to an embodiment of the inventive concept. For concise description, the same element in the image sensor according to the previous embodiment may be identified by the same reference number without repeating an overlapping description thereof.

Referring to FIGS. 14 and 16, the image sensor may include a plurality of pixel groups PGX. Each of the pixel groups PGX may include at least 4, 8, 9, or 16 pixel regions PR1 to PR4. In each pixel group GPX, the pixel regions PR1 to PR4 may be arranged in the first and second directions D1 and D2, which are not parallel to each other, and in a matrix shape. In an embodiment, the first to fourth pixel regions PR1 to PR4 may constitute a single pixel group GPX. In an embodiment, each pixel group GPX is illustrated to include four pixel regions, but the inventive concept is not limited to this example.

First to fourth photoelectric conversion regions 110a to 110d may be provided in the first to fourth pixel regions PR1 to PR4, respectively. The first to fourth photoelectric conversion regions 110a to 110d may be impurity regions that are doped with dopants of the second conductivity type.

The first active portion ACT1 and the second active portion ACT2 may be provided in each of the first to fourth pixel regions PR1 to PR4 by the shallow trench isolation pattern STI provided in the first surface 100a of the semiconductor substrate 100. The first and second active portions ACT1 and ACT2 may be defined by the shallow trench isolation pattern STI adjacent to the first surface 100a of the semiconductor substrate 100.

The first to fourth transfer gate electrodes TG1, TG2, TG3, and TG4 may be provided in the first to fourth pixel regions PR1 to PR4, respectively. Each of the first to fourth transfer gate electrodes TG1 to TG4 may have a dual vertical gate structure, which includes two vertical portions extended into the semiconductor substrate 100, as described above. In the first to fourth pixel regions PR1 to PR4, the first to fourth transfer gate electrodes TG1, TG2, TG3, and TG4 may be formed of or include polysilicon that is doped with dopants of the first conductivity type, as described above.

First to fourth floating diffusion regions FD1 to FD4 may be respectively provided in portions of the first active portions ACT1 that are located near the first to fourth transfer gate electrodes TG1 to TG4. The first to fourth floating diffusion regions FD1 to FD4 may be disposed to be adjacent to each other and may be disposed in a center portion of each pixel group PGX.

In each of the first to fourth pixel regions PR1 to PR4, a pixel transistor may be provided on the second active portion ACT2. The first to fourth pixel gate electrodes PG1, PG2, PG3, and PG4 may be provided on the second active portions ACT2 in the first to fourth pixel regions PR1 to PR4, respectively. The first to fourth pixel gate electrodes PG1 to PG4 may be formed of or include polysilicon that is doped with dopants of the first conductivity type, as described above.

At least one of the pixel transistors on the first to fourth pixel regions PR1 to PR4 may be a fin-type transistor. That is, the fin active patterns FP may be disposed between the second active portions ACT2 and the first to fourth pixel gate electrodes PG1 to PG4. In an embodiment, some of the pixel transistors on the first to fourth pixel regions PR1 to PR4 may be planar-type transistors, as described above.

In an embodiment, the pixel transistor may include a channel region between the source/drain regions, and the channel region may contain dopants of the second conductivity type.

Referring to FIG. 15, a common active portion ACT may be commonly provided on the first to fourth pixel regions PR1 to PR4, and the second active portion ACT2 may be provided in each of the pixel regions PR1 to PR4.

In the first to fourth pixel regions PR1 to PR4, the first to fourth transfer gate electrodes may be provided on the common active portion ACT, respectively.

In every pixel group GPX, a common floating diffusion region CFD may be provided in the common active portion ACT. In an embodiment, the common floating diffusion region CFD may be commonly provided in at least four pixel regions PR1 to PR4. The first portions Pa of the isolation structure PIS may be spaced apart from each other in the first direction D1 with the common floating diffusion region CFD interposed therebetween, and the second portions Pb may be spaced apart from each other in the second direction D2 with the common floating diffusion region CFD interposed therebetween. The common floating diffusion region FD may be provided in a portion of the semiconductor substrate 100 adjacent to the first to fourth transfer gate electrodes TG1 to TG4.

The first to fourth pixel gate electrodes PG1, PG2, PG3, and PG4 may be provided on the second active portions ACT2 in the first to fourth pixel regions PR1 to PR4, respectively. In the first to fourth pixel regions PR1 to PR4, the first to fourth transfer gate electrodes TG1 to TG4 and the first to fourth pixel gate electrodes PG1 to PG4 may be formed of or include polysilicon that is doped with dopants of the first conductivity type, as described above.

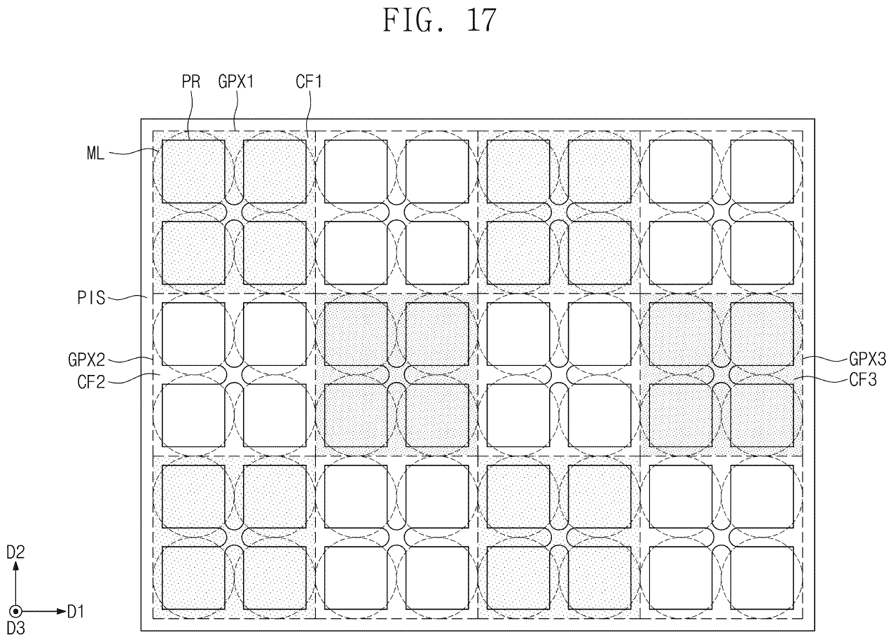

FIG. 17 is a plan view illustrating an image sensor according to an embodiment of the inventive concept.

Referring to FIG. 17, the image sensor may include first to third pixel groups GPX1, GPX2, and GPX3, which are two-dimensionally arranged in the first and second directions D1 and D2. In the odd-numbered rows, the first and second pixel groups GPX1 and GPX2 may be alternately and repeatedly arranged. In the even-numbered rows, the second and third pixel groups GPX2 and GPX3 may be alternately and repeatedly arranged. Each of the first to third pixel groups GPX1, GPX2, and GPX3 may include pixel regions PR arranged in the 2×2 shape. The isolation structure PIS may be provided to separate the first to third pixel groups GPX1, GPX2, and GPX3 from each other. The isolation structure PIS may be inserted into each of the pixel groups GPX1, GPX2, and GPX3 to separate the pixel regions PR from each other, when viewed in a plan view. However, the isolation structure PIS may be provided to cut each of the pixel groups GPX1, GPX2, and GPX3 at the center thereof, and the pixel regions PR in a single pixel group may be connected to each other. A first pixel group GPX1 may be covered with a first color filter CF1. A second pixel group GPX2 may be covered with a second color filter CF2. A third pixel group GPX3 may be covered with a third color filter CF3. The first color filter CF1 may have one of red, green, and blue colors. The second color filter CF2 may have another color of red, green, and blue colors. The third color filter CF3 may have the remaining one of red, green, and blue colors. Micro lenses ML may be disposed on the first to third color filters CF1, CF2, and CF3. The micro lenses ML may be disposed to correspond to and overlap with the pixel regions PR, respectively. That is, the micro lenses ML may be disposed on the pixels PX, respectively. The micro lenses ML, which are arranged in a 2×2 shape, may be disposed on each of the pixel groups GPX1, GPX2, and GPX3. The afore-described arrangement of the micro lens ML may enhance the light collection efficiency in each of the pixel regions PR, thereby achieving a clear image.

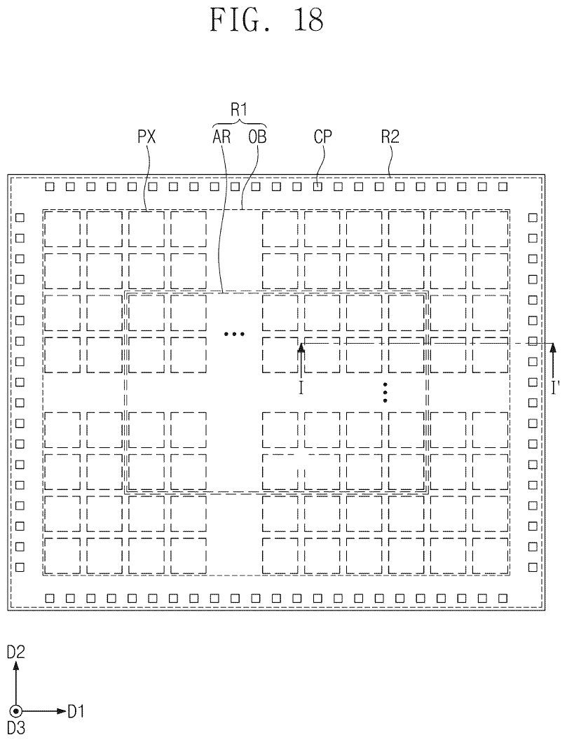

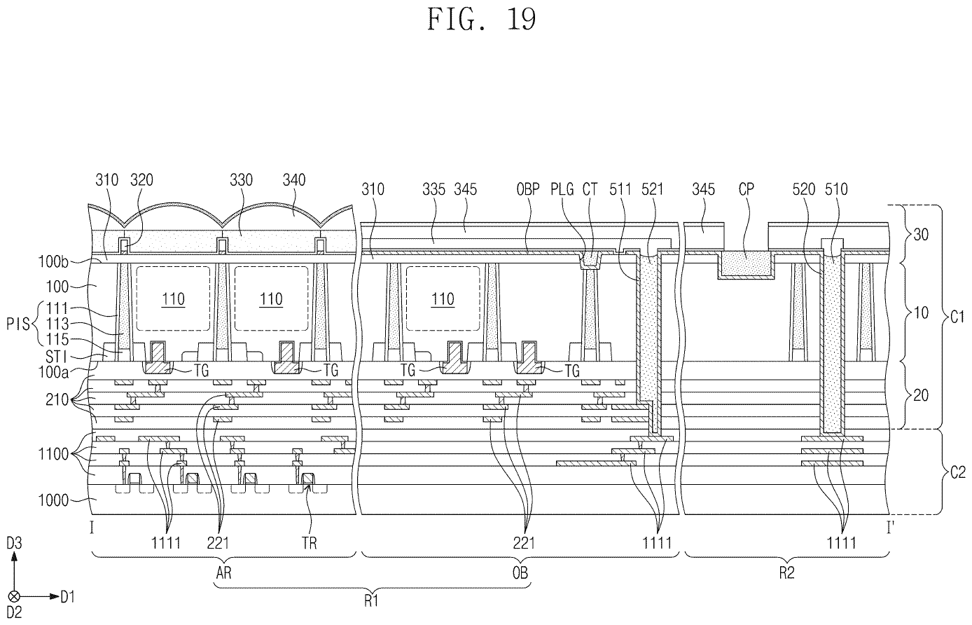

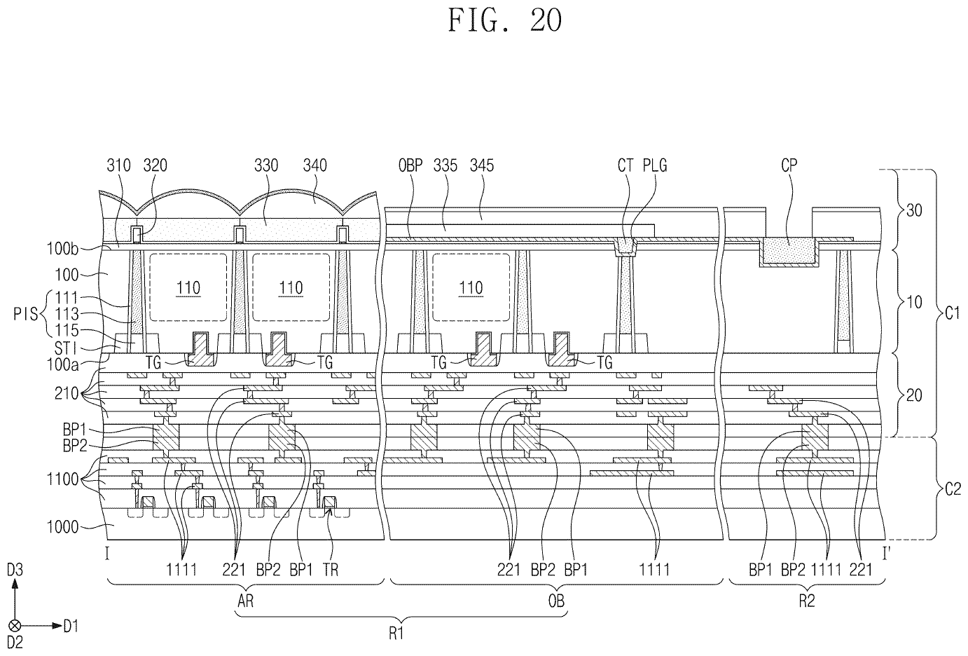

FIG. 18 is a plan view schematically illustrating an image sensor according to an embodiment of the inventive concept. FIGS. 19 and 20 are sectional views, which are taken along a line I-I′ of FIG. 18 to illustrate an image sensor according to an embodiment of the inventive concept.

Referring to FIGS. 18 and 19, the image sensor may include a sensor chip C1 and a logic chip C2. The sensor chip C1 may include a pixel array region R1 and a pad region R2, and the pixel array region R1 may include transfer gate electrodes TG.

The pixel array region R1 may include a plurality of unit pixels P, which are two-dimensionally arranged in two different directions (e.g., in the first and second directions D1 and D2). Each of the unit pixels P may include a photoelectric conversion device and readout devices. An electrical signal, which is generated by an incident light, may be output from each of the unit pixels P of the pixel array region R1.

The pixel array region R1 may include a light-receiving region AR and a light-blocking region OB. The light-blocking region OB may be provided to enclose the light-receiving region AR, when viewed in a plan view. For example, the light-blocking region OB may be provided to enclose the light-receiving region AR in four different directions (e.g., up, down, left, and rights directions), when viewed in a plan view. In an embodiment, reference pixels, to which light is not incident, may be provided in the light-blocking region OB, and in this case, by comparing a charge amount obtained by sensing the unit pixel P in the light-receiving region AR, with an amount of reference charges produced in the reference pixels, it may be possible to calculate a magnitude of an electrical signal sensed from the unit pixel P.

A plurality of conductive pads CP, which are used to input or output control signals and photoelectric signals, may be disposed in the pad region R2. The pad region R2 may be provided to enclose the pixel array region R1, when viewed in a plan view, and in this case, the image sensor may be easily connected to an external device. The conductive pads CP may be used to input/output electrical signals, which are generated in the unit pixels P, to an external device.

In the light-receiving region AR, the sensor chip C1 may have the same technical features as the image sensor described above. That is, the sensor chip C1 may include the photoelectric conversion circuit layer 10, which is provided between the pixel circuit layer 20 and the optically-transparent layer 30 in a vertical direction, as described above. The photoelectric conversion circuit layer 10 of the sensor chip C1 may include the semiconductor substrate 100, the isolation structure PIS defining the pixel regions, and photoelectric conversion regions 110 provided in the pixel regions, as described above. The isolation structure PIS may have substantially the same structure on the light-receiving region AR and the light-blocking region OB. The isolation structure PIS may be disposed in the semiconductor substrate 100 of the light-blocking region OB. The gap-fill pattern 113 of the isolation structure PIS may be electrically connected to a back-side contact plug PLG, in the light-blocking region OB. The gap-fill pattern 113 may be applied with a specific bias through the back-side contact plug PLG. The back-side contact plug PLG may have a width lager than the isolation structure PIS. The back-side contact plug PLG may be formed of or include at least one of metallic materials and/or metal nitride materials. For example, the back-side contact plug PLG may be formed of or include titanium and/or titanium nitride.

The contact pattern CT may be buried in a contact hole with the back-side contact plug PLG. The contact pattern CT may include a material different from the back-side contact plug PLG. For example, the contact pattern CT may be formed of or include aluminum (Al).

The contact pattern CT and the back-side contact plug PLG may be electrically connected to the gap-fill pattern 113 of the isolation structure PIS. A positive bias may be applied to the gap-fill pattern 113 of the isolation structure PIS through the contact pattern CT, and the positive bias may be transferred from the light-blocking region OB to the light-receiving region AR. In this case, it may be possible to reduce a dark current produced at an interface between the isolation structure PIS and the semiconductor substrate 100.

In the light-blocking region OB, the optically-transparent layer 30 may include a light-blocking pattern OBP, a filtering layer 335, and an organic layer 345. In an embodiment, the isolation structure PIS may be continuously extended from the light-receiving region AR to the light-blocking region OB.

In the light-blocking region OB, the light-blocking pattern OBP may be disposed on a top surface of the planarization insulating layer 310. The light-blocking pattern OBP may be formed of or include the same material as the conductive pattern of the grid 320 in the light-receiving region AR. That is, the light-blocking pattern OBP may include a metal pattern and a metal oxide pattern. The light-blocking pattern OBP may be formed of or include at least one of, for example, titanium nitride and titanium oxynitride. The light-blocking pattern OBP may not be extended to the light-receiving region AR.

The light-blocking pattern OBP may limit and/or prevent light from being incident into the photoelectric conversion regions PD, which are provided in the light-blocking region OB. The photoelectric conversion regions PD in the reference pixel regions of the light-blocking region OB may be configured to output a noise signal, without a photoelectric signal. The noise signal may be produced by electrons, which are generated by heat or a dark current.

The filtering layer 335 may cover the light-blocking pattern OBP, in the light-blocking region OB. The filtering layer 335 may be provided to block light having a wavelength different from the color filters 330. For example, the filtering layer 335 may be configured to block the infrared light. The filtering layer 335 may include a blue color filter, but the inventive concept is not limited to this example.

The organic layer 345 and a passivation layer may be provided on the filtering layer 335, in the light-blocking region OB and the pad region R2. The organic layer 345 may include the same material as the micro lenses 340.

In the light-blocking region OB, a first penetration conductive pattern 511 may be provided to penetrate the semiconductor substrate 100 and to electrically connect a metal line of the pixel circuit layer 20 to an interconnection structure 1111 of the logic chip C2. The first penetration conductive pattern 511 may have a first bottom surface and a second bottom surface, which are located at different levels. A first gap-fill pattern 521 may be provided within the first penetration conductive pattern 511. The first gap-fill pattern 521 may be formed of or include a low-refractive material and may exhibit an insulating property.

In the pad region R2, the conductive pads CP may be provided on the second surface 100b of the semiconductor substrate 100. The conductive pads CP may be buried in portions of the semiconductor substrate 100 located near the second surface 100b. In an embodiment, the conductive pads CP may be provided in pad trenches, which are formed in the second surface 100b of the semiconductor substrate 100 and are located in the pad region R2. The conductive pads CP may be formed of or include at least one of metallic materials (e.g., aluminum, copper, tungsten, titanium, tantalum, or alloys thereof). In a mounting process of an image sensor, bonding wires may be bonded to the conductive pads CP. The conductive pads CP may be electrically connected to an external device through the bonding wires.

In the pad region R2, a second penetration conductive pattern 520 may be provided to penetrate the semiconductor substrate 100 and may be electrically connected to the interconnection structure 1111 of the logic chip C2. The second penetration conductive pattern 520 may be extended to a region on the second surface 100b of the semiconductor substrate 100 and may be electrically connected to the conductive pads CP. A portion of the second penetration conductive pattern 520 may cover bottom and side surfaces of the conductive pads CP. A second gap-fill pattern 510 may be provided in the second penetration conductive pattern 520. The second gap-fill pattern 510 may include a low refractive material and may have an insulating property. In the pad region R2, the isolation structures PIS may be provided around the second penetration conductive pattern 520.

The logic chip C2 may include a logic semiconductor substrate 1000, logic circuits TR, interconnection structures 1111 connected to the logic circuits TR, and logic interlayer insulating layers 1100. The uppermost layer of the logic interlayer insulating layers 1100 may be bonded to the pixel circuit layer 20 of the sensor chip C1. The logic chip C2 may be electrically connected to the sensor chip C1 through the first and second penetration conductive patterns 511 and 520.

In an embodiment, the sensor and logic chips C1 and C2 are illustrated to be electrically connected to each other through the first and second penetration conductive patterns 511 and 520, but the inventive concept is not limited to this example.

In the embodiment of FIG. 20, the first and second penetration conductive patterns may be omitted, and since bonding pads, which are provided in the uppermost metal layers of the sensor and logic chips C1 and C2, are directly bonded to each other, the sensor chip C1 and the logic chip C2 may be electrically connected to each other.

In the sensor chip C1, the gap-fill pattern 113 of the isolation structure PIS, which is extended from the light-receiving region AR to the light-blocking region OB, may be connected to the back-side contact plug PLG, in the light-blocking region OB.

Furthermore, the sensor chip C1 may include first bonding pads BP1, which are provided in the uppermost metal layer of the pixel circuit layer 20, and the logic chip C2 may include second bonding pads BP2, which are provided in the uppermost metal layer of the interconnection structure 1111. The first and second bonding pads BP1 and BP2 may be formed of or include at least one of, for example, tungsten (W), aluminum (Al), copper (Cu), tungsten nitride (WN), tantalum nitride (TaN), or titanium nitride (TiN).

The first bonding pads BP1 of the sensor chip C1 and the second bonding pads BP2 of the logic chip C2 may be electrically and directly connected to each other by a hybrid bonding method. Here, the hybrid bonding method may mean a method of bonding two materials of the same kind at an interface therebetween (e.g., through a fusion process). For example, in the case where the first and second bonding pads BP1 and BP2 are formed of copper (Cu), they may be physically and electrically connected to each other in a Cu-Cu bonding manner. In addition, insulating layers of the sensor and logic chips C1 and C2 may be bonded to each other in a dielectric-dielectric bonding manner.

According to an embodiment of the inventive concept, since pixel gate electrodes constituting pixel transistors of a unit pixel contain dopants of a first conductivity type, the threshold voltage of the pixel transistor may be increased. Even if the unit pixel is miniaturized, the threshold voltage of the pixel transistor may still be secured. Furthermore, the linearity of the output characteristics of a source follower transistor may be improved under low-light conditions. In addition, the leakage current characteristics of the source follower transistor may be improved.

While example embodiments of the inventive concept have been particularly shown and described, it will be understood by one of ordinary skill in the art that variations in form and detail may be made therein without departing from the spirit and scope of the attached claims.

What is claimed is:

1. An image sensor, comprising:
a semiconductor substrate of a first conductivity type;
an isolation structure in the semiconductor substrate, the isolation structure defining pixel regions;
a shallow trench isolation pattern in the semiconductor substrate, the shallow trench isolation pattern defining an active portion in each of the pixel regions;
a transfer gate electrode between a photoelectric conversion region and a floating diffusion region, in each of the pixel regions; and
pixel transistors in the pixel regions, respectively,
wherein each of the pixel transistors comprises
a pixel gate electrode on the active portion, and
source/drain regions in the active portion at both sides of the pixel gate electrode,
wherein the transfer gate electrodes on the pixel regions and the pixel gate electrodes of the pixel transistors comprise dopants of the first conductivity type, and
the source/drain regions comprise dopants of a second conductivity type.

2. The image sensor of claim 1, wherein
at least one of the pixel transistors comprises a channel region between the source/drain regions, and
the channel region comprises the dopants of the second conductivity type.

3. The image sensor of claim 1, wherein a first pixel transistor of the pixel transistors further comprises fin active patterns between the active portion and the pixel gate electrode.

4. The image sensor of claim 3, wherein the fin active patterns comprise the dopants of the first conductivity type or the dopants of the second conductivity type.

5. The image sensor of claim 3, wherein top surfaces of the fin active patterns are coplanar with a first surface of the semiconductor substrate.

6. The image sensor of claim 3, wherein
a vertical portion of the transfer gate electrode penetrates a portion of the semiconductor substrate,
the vertical portion of the transfer gate electrode has a first bottom surface,
the first bottom surface is at a level lower than a top surface of the semiconductor substrate,
the pixel gate electrode of the first pixel transistor has a second bottom surface, and
the second bottom surface is at a level between a first surface of the semiconductor substrate and the first bottom surface.

7. The image sensor of claim 1, wherein
a first pixel transistor and a second pixel transistor are among the pixel transistors,
the first pixel transistor further comprises fin active patterns between the active portion and the pixel gate electrode,
the pixel gate electrode of the first pixel transistor crosses the fin active patterns, and
a bottom surface of the pixel gate electrode of the second pixel transistor is parallel to a first surface of the semiconductor substrate.

8. The image sensor of claim 1, wherein a vertical portion of the transfer gate electrode vertically penetrates a portion of the semiconductor substrate.

9. The image sensor of claim 8, wherein
the vertical portion of the transfer gate electrode has a first bottom surface,
the first bottom surface is at a level lower than a first surface of the semiconductor substrate, and
the pixel gate electrode has a second bottom surface, and
the second bottom surface is at a level between the first surface of the semiconductor substrate and the first bottom surface.

10. The image sensor of claim 1, wherein
the transfer gate electrode comprises a first vertical gate and a second vertical gate, and
the first vertical gate and the second vertical gate extend into the semiconductor substrate.

11. The image sensor of claim 1, wherein
in each of the pixel regions, the photoelectric conversion region comprise a first photoelectric conversion region and a second photoelectric conversion region,
in each of the pixel regions, the floating diffusion region comprises a first floating diffusion region and a second floating diffusion region, and
in each of the pixel regions, the transfer gate electrode comprises a first transfer gate electrode between the first photoelectric conversion region and the first floating diffusion region and a second transfer gate electrode between the second photoelectric conversion region and the second floating diffusion region.

12. The image sensor of claim 11, wherein the pixel gate electrodes of the pixel transistors comprise a first pixel gate electrode and a second pixel gate electrode overlapping the first photoelectric conversion region and the second photoelectric conversion region, respectively.

13. An image sensor, comprising:
a semiconductor substrate of a first conductivity type;
an isolation structure in the semiconductor substrate, the isolation structure defining pixel regions;
a shallow trench isolation pattern in the semiconductor substrate, the shallow trench isolation pattern defining an active portion in each of the pixel regions to provide active portions in the pixel regions, respectively;
a photoelectric conversion region in each of the pixel regions and in the semiconductor substrate, the photoelectric conversion region comprising dopants of a second conductivity type;
a floating diffusion region in each of the pixel regions and in the semiconductor substrate, the floating diffusion region being spaced apart from the photoelectric conversion region;
a transfer gate electrode between the photoelectric conversion region and the floating diffusion region, in each of the pixel regions;
a source follower gate electrode on a first active portion, which is one of the active portions in the pixel regions;
first fin active patterns between the first active portion and the source follower gate electrode; and
first source/drain regions in the first active portion at both sides of the source follower gate electrode,
wherein the transfer gate electrode and the source follower gate electrode comprise the dopants of the first conductivity type.

14. The image sensor of claim 13, wherein the first source/drain regions comprise the dopants of the second conductivity type.

15. The image sensor of claim 13, wherein
a bottom surface of the transfer gate electrode and a bottom surface of the source follower gate electrode are at a level lower than a first surface of the semiconductor substrate.

16. The image sensor of claim 13, wherein
the first fin active patterns comprise a first channel region between the first source/drain regions, and
the first channel region comprises the dopants of the second conductivity type.

17. The image sensor of claim 13, further comprising:
a pixel gate electrode on a second active portion among the active portions in the pixel regions; and
second source/drain regions in the second active portion at both sides of the pixel gate electrode,
wherein the pixel gate electrode comprises the dopants of the first conductivity type.

18. The image sensor of claim 17, further comprising:
second fin active patterns between the second active portion and the pixel gate electrode,
wherein a bottom surface of the pixel gate electrode is coplanar with a bottom surface of the source follower gate electrode.

19. An image sensor, comprising:
a semiconductor substrate of a first conductivity type, wherein a first surface of the semiconductor substrate is opposite a second surface of the semiconductor substrate;
an isolation structure in the semiconductor substrate, the isolation structure defining a first pixel region, a second pixel region, a third pixel region, and a fourth pixel region in the semiconductor substrate, the first pixel region, the second pixel region, the third pixel region, and the fourth pixel region each including
a first photoelectric conversion region, a second photoelectric conversion region, a third photoelectric conversion region, and a fourth photoelectric conversion region, and
a first floating diffusion region, a second floating diffusion region, a third floating diffusion region, and a fourth floating diffusion region in the first pixel region, the second pixel region, the third pixel region, and the fourth pixel region, respectively, and spaced apart from the first photoelectric conversion region, the second photoelectric conversion region, the third photoelectric conversion region, and the fourth photoelectric conversion region;
a plurality of transfer gate electrodes each having a bottom surface at a level between the first surface of the semiconductor substrate and the second surface of the semiconductor substrate,
the plurality of transfer gate electrodes including a first transfer gate electrode between the first photoelectric conversion region and the first floating diffusion region, a second transfer gate electrode between the second photoelectric conversion region and the second floating diffusion region, a third transfer gate electrode between the third photoelectric conversion region and the third floating diffusion region, and a fourth transfer gate electrode between the fourth photoelectric conversion region and the fourth floating diffusion region;
a shallow trench isolation pattern adjacent to the first surface of the semiconductor substrate, the shallow trench isolation pattern defining an active portion in each of the first pixel region, the second pixel region, the third pixel region, and the fourth pixel region to provide active portions, respectively, in the first pixel region, the second pixel region, the third pixel region, and the fourth pixel region;
pixel transistors on the active portions, respectively, in the first pixel region, the second pixel region, the third pixel region, and the fourth pixel region;
color filters on the second surface of the semiconductor substrate, the color filters respectively corresponding to the first pixel region, the second pixel region, the third pixel region, and the fourth pixel region;
a grid between the color filters, the grid overlapping the isolation structure; and
micro lenses on the color filters,
wherein each of the pixel transistors comprises fin active patterns, a pixel gate electrode crossing the fin active patterns, and source/drain regions in the active portion at both sides of the pixel gate electrode,
wherein, in each of the pixel transistors, the fin active patterns protrude from the active portion in each of the first pixel region, the second pixel region, the third pixel region, and the fourth pixel region,
wherein the pixel gate electrodes of the pixel transistors, the first transfer gate electrode, the second transfer gate electrode, the third transfer gate electrode, and the fourth transfer gate electrode comprise dopants of the first conductivity type, and
the source/drain regions of the pixel transistors comprise dopants of a second conductivity type.

20. The image sensor of claim 19, wherein
at least one of the pixel transistors comprises a channel region in the fin active patterns between the source/drain regions, and
the channel region comprises the dopants of the second conductivity type.
